(19) United States
(12) Patent Application Publication
(10) Pub. No.: US 2026/0320431 A1
(43) Pub. Date: Oct. 15, 2026

(54) Computerized analysis of a trained machine learning model

(71) Applicant: Citrusx Ltd., Tel-Aviv (IL)

(72) Inventor: Gilad MANOR, Herzliya (IL)

(21) Appl. No.: 18/998,751

(22) PCT Filed: Jul. 24, 2023
(86) PCT No.: PCT/IL2023/050770

§ 371 Date: Jan. 27, 2025

(30) Foreign Application Priority Data
Jul. 27, 2022 (IL) 295124

(51) Int. Cl. G06N 5/04

(52) U.S. Cl. CPC G06N 5/04

(57) ABSTRACT

There are provided systems and method comprising, by a processor and memory circuitry, obtaining, for a machine learning model, a set of data points, informative of a set of input vectors and of a set of predicted vectors, wherein each input vector of the set of input vectors has been used to train the machine learning model, using the set of data points to generate a database informative of the machine learning model, wherein the database is informative of terminal nodes, each given terminal being associated with: a plurality of data points of the set, one or more coefficients defining a function fitting a relationship between a plurality of input vectors of the given terminal node and a plurality of predicted vectors of the given terminal node, with a quality meeting an accuracy criterion, wherein the database is usable to generate data informative of the machine learning model.

### PRIORITY DATA

This patent application claims priority of the Israeli patent application IL295124 filed on Jul. 27, 2022.

### TECHNICAL FIELD

The presently disclosed subject matter relates to the field of machine learning models.

### BACKGROUND

In various technical fields (e.g., biological or medical field, business field, physics field, statistics field, etc.), a machine learning model is trained to model a phenomenon.

Generally, the machine learning is trained to predict, based on an input vector informative of one or more features, an output vector informative of one or more features.

Once the machine learning model has been trained, a complex model is obtained, which generally involves a plurality of weights and layers.

A technical challenge resides in the fact that it is cumbersome to understand whether the machine learning model has been adequately trained, and how to improve this training. In addition, the behavior of the machine learning model, after its training, is difficult to understand.

There is therefore a need to provide new systems and methods which enable a computerized analysis of a trained machine learning model.

### GENERAL DESCRIPTION

In accordance with certain aspects of the presently disclosed subject matter, there is provided a method comprising, by a processor and memory circuitry (PMC): obtaining, for a machine learning model, a set of data points, informative of a set of input vectors and of a set of predicted vectors, wherein each input vector of the set of input vectors has been used to train the machine learning model, wherein each given data point of the set of data points is associated with a given input vector of the set of input vectors and a given predicted vector of the set of predicted vectors, wherein the given predicted vector has been generated by the machine learning model using the given input vector, using the set of data points to generate a database informative of the machine learning model, wherein the database is informative of a plurality of nodes comprising terminal nodes, wherein each given terminal node is associated with a plurality of data points of the set of data points, one or more coefficients defining a function, wherein the function fits a relationship between a plurality of input vectors of the plurality of data points of the given terminal node, and a plurality of predicted vectors of the plurality of data points of the given terminal node, with a quality meeting an accuracy criterion, wherein the database is usable to generate data informative of the machine learning model.

In addition to the above features, the method according to this aspect of the presently disclosed subject matter can optionally comprise one or more of features (i) to (xliii) below, in any technically possible combination or permutation:
i. the method comprises using the database for determining data informative of a quality of the training of the machine learning model;
ii. the method comprises using the database for determining a certainty of the machine learning model in its prediction;
iii. the method comprises using the database for determining a certainty of a prediction generated by the machine learning model depending on a range of values of input vectors fed to the machine learning model;
iv. the method comprises using the database for providing a recommendation of whether the machine learning model has to be retrained;
v. the method comprises using the database for providing a recommendation on a range of values of input vectors for which the machine learning model has to be retrained;
vi. the method comprises using the database for determining one or more input variables of the input vectors which most impact a prediction generated by the machine learning model;
vii. the method comprises using the database for determining a change in one or more values of a given input vector to obtain a prediction, by the machine learning model, which matches a desired predicted vector;
viii. the method comprises using the database for a given input vector, estimating a prediction which would have been generated by the machine learning model using this given input vector;
ix. the method comprises using the database for determining data informative of a bias in a prediction of the machine learning model;
x. each input vector comprises one or more values for one or more input variables and each predicted vector comprises one or more values for one or more output variables, wherein, for a given terminal node, the function defines a relationship between the input variables and the output variables, determined using the plurality of input vectors of the given terminal node and the plurality of predicted vectors of the given terminal node;
xi. for a function of at least one terminal node, each given input variable is associated with data D_{stat_sign} informative of a statistical significance of the input variable;
xii. for a function of at least one terminal node, each input variable is associated with a coefficient in the function;
xiii. the method comprises, for one or more of the input variables, using a magnitude of a coefficient associated with the input variable to determine data informative of an impact of the given input variable on a prediction of the machine learning model;
xiv. each terminal node is associated with a first set of boundaries B_{terminal_node_input} defining boundaries of a space in which all of the plurality of input vectors of the data points of the terminal node are located, wherein the method comprises, for one or more of the input variables, using a magnitude of a coefficient associated with the input variable to determine data informative of an impact of the given input variable on a prediction of the machine learning model in a range of input values located within the first set of boundaries;
xv. the method comprises using coefficients associated with the input variables to determine whether the machine learning model relies more on a limited subset of one or more input variables than one or more input variables which are not part of the subset to generate its prediction;
xvi. the function is determined using a regression analysis;
xvii. the function is a linear function;
xviii. at least one terminal node is further associated with one or more data points, each of these data points including an input vector which have not been used to train the machine learning model and a predicted vector generated by the machine learning model using the input vector;
xix. each given terminal node is associated with a first set of boundaries B_{terminal_node_input} defining boundaries of a space in which all of the plurality of input vectors of all data points associated with the given terminal node are located;
xx. the plurality of nodes includes non-terminal nodes and terminal nodes, wherein at least one non-terminal node is linked to one or more child nodes, each child node being either a non-terminal node or a terminal node, said at least one non-terminal node being associated with a first set of boundaries B_{node_input} defining boundaries of a space in which all of the plurality of input vectors of all data points of said one or more child nodes are located;
xxi. any data point including an input vector of the set of input vectors and a corresponding predicted vector of the set of predicted vectors is associated with a single terminal node of the database;
xxii. the plurality of nodes is arranged in hierarchical levels Lᵢ, with i from 1 to N, wherein each node of level Lⱼ is linked to a parent node of level Lⱼ₋₁, with j from 2 to N, wherein each node is associated with a first set of boundaries B_{node_input} defining boundaries of a space including input vectors of all data points associated with this node, wherein, for each given node linked to a parent node, a space defined by the first set of boundaries of the given node is included within the space defined by the first set of boundaries of the parent node;
xxiii. generating the database comprises: (1) obtaining a given node associated with a plurality of data points of the set of data points, (2) determining coefficients defining a function which fits a relationship between the plurality of input vectors and the plurality of predicted vectors of the data points of the given node, (3) determining whether the function fits the relationship between the plurality of input vectors and the plurality of predicted vectors of the data points of the given node with a quality meeting an accuracy criterion, (4) for a function for which said quality does not meet the accuracy criterion: generating N child nodes linked to the given node, with N≥1, each given child node being associated with a given fraction of the data points of the parent node, and repeating (1) to (3) for each given child node, wherein said repeating of (1) to (3) for each given child node comprises using the given child node as the given node in (1) to (3);
xxiv. upon determination at (3) that the function fits the relationship between the plurality of input vectors and the plurality of predicted vectors of the data points of the given node with a quality meeting the accuracy criterion, the method comprises storing the given node as a terminal node in the database;
xxv. for a given child node being associated with a given number M₁ of data points which is below a threshold, the method comprises obtaining one or more additional input vectors which have not been used to train the machine learning model, using the one or more additional input vectors to generate, by the machine learning model, additional predicted vectors, and associating data points including the additional input vectors and the additional predicted vectors with the given child node;
xxvi. the given number M₁ of data points only include input vectors which have been used to train the machine learning model;
xxvii. the given child node is associated with a first set of boundaries B_{node_input} defining boundaries of a space including the M₁ input vectors of the data points associated with the given child node, wherein the one or more additional input vectors are selected within the first set of boundaries B_{node_input};
xxviii. each input vector comprises one or more values for one or more input variables, each terminal node of the plurality of terminal nodes of the database is associated with a first set of boundaries B_{terminal_node_input} defining boundaries of a space in which all values of the plurality of input vectors of the data points of said terminal node are located, wherein the method comprises: obtaining a data point comprising a first vector comprising one or more values for the one or more input variables, and using the database to determine a given terminal node for which the first vector is located within the space defined by the first set of boundaries B_{terminal_node_input} of said given terminal node;
xxix. each input vector comprises one or more values for one or more input variables, each predicted vector comprises one or more values for one or more output variables, each terminal node of the plurality of terminal nodes of the database is associated with a first set of boundaries B_{terminal_node_input} defining boundaries of a space in which all values of the plurality of input vectors of all data points of said terminal node are located, wherein the method comprises: obtaining a first vector comprising one or more values for the one or more input variables, using the database to determine a given terminal node for which the first vector is located within the space defined by the first set of boundaries B_{terminal_node_input} of said given terminal node, and using the function associated with said given terminal node and the first vector to determine a second vector comprising one or more values for the one or more output variables;
xxx. each input vector is informative of M input variables, wherein the method comprises, for at least one terminal node, obtaining a number N₁ of data points associated with the terminal node which include an input vector which has been used to train the machine learning model, and using N₁ and M to determine data D_{certainty} informative of the certainty of the machine learning model associated with the terminal node;
xxxi. each terminal node of the plurality of terminal nodes of the database is associated with a first set of boundaries B_{terminal_node_input} defining boundaries of a space in which all values of the plurality of input vectors of all data points of said terminal node are located, wherein, the method comprises determining a lack of certainty of the machine learning model within the first set of boundaries B_{terminal_node_input};
xxxii. the method comprises obtaining, for a first machine learning model, a first set of data points, informative of a first set of input vectors and of a first set of predicted vectors, wherein each input vector of the first set of input vectors has been used to train the machine learning model, wherein each given data point of the first set of data points is associated with a given input vector of the first set of input vectors, and a given predicted vector of the first set of predicted vectors, wherein the given predicted vector has been generated by the machine learning model using the given input vector, using the first set of data points to generate a first database informative of the first machine learning model, wherein the first database is informative of a plurality of nodes comprising terminal nodes, wherein, for at least part of the terminal nodes, each given terminal node is associated with a plurality of data points of the first set of data points, one or more coefficients defining a function, wherein the function fits a relationship between a plurality of input vectors of the plurality of data points of the given terminal node, and a plurality of predicted vectors of the plurality of data points of the given terminal node, with a quality meeting an accuracy criterion, obtaining, for a second machine learning model, a second set of data points, informative of a second set of input vectors and of a second set of predicted vectors, wherein each input vector of the second set of input vectors has been used to train the machine learning model, wherein each given data point of the second set of data points is associated with a given input vector of the second set of input vectors, and a given predicted vector of the second set of predicted vectors, wherein the given predicted vector has been generated by the machine learning model using the given input vector, using the second set of data points to generate a second database informative of the second machine learning model, wherein the second database is informative of a plurality of nodes comprising terminal nodes, wherein, for at least part of the terminal nodes, each given terminal node is associated with a plurality of data points of the second set of data points, one or more coefficients defining a function, wherein the function fits a relationship between a plurality of input vectors of the plurality of data points of the given terminal node, and a plurality of predicted vectors of the plurality of data points of the given terminal node, with a quality meeting an accuracy criterion, using the first database and the second database to compare data informative of the first machine learning model with data informative of the second machine learning model;
xxxiii. at least some of the second input vectors used to train the second machine learning model are different from the first input vectors used to train the first machine learning model;
xxxiv. the second machine learning model corresponds to the first machine learning model after a retraining using second input vectors different from the first input vectors;
xxxv. an architecture of the second machine learning model differs from an architecture of the first machine learning model;
xxxvi. the method comprises determining, for a given input vector, a first terminal node of the first database for which a first set of boundaries of the first terminal node contains the given input vector, determining, for the given input vector, a second terminal node of the first database for which a first set of boundaries of the second terminal node contains the given input vector, and comparing data associated with the first terminal node with data associated with the second terminal node;
xxxvii. the method comprises comparing data informative of a certainty of the first machine learning model associated with the first terminal node with data informative of a certainty of the second machine learning model associated with the second terminal node;
xxxviii. the method comprises comparing a goodness-of-fit measure associated with the function of the first terminal node with a goodness-of-fit measure associated with the function of the second terminal node;
xxxix. the method comprises comparing a level of the first terminal node within the first database with a level of the second terminal node within the second database;
xl. the method comprises comparing, for at least one input variable, data D_{stat_sign} informative of a statistical significance of the input variable in the first terminal node with data D_{stat_sign} informative of a statistical significance of the input variable in the second terminal node,
xli. the method comprises comparing, for at least one input variable, a magnitude of a coefficient associated with this input variable for the first terminal node with a magnitude of a coefficient associated with this input variable for the second terminal node;
xlii. the method comprises determining, for a given input vector, a first terminal node of the first database for which a first set of boundaries of the first terminal node contains the given input vector, wherein, when the second database does not include any terminal node which has a first set of boundaries defining a space including the given input vector, outputting alerting data; and
xliii. each input vector comprises one or more values for one or more input variables, each predicted vector comprises one or more values for one or more output variables, wherein the method comprises obtaining a first input vector comprising one or more values for the one or more input variables, wherein the machine learning model is operative to generate a first predicted vector by using the first input vector, wherein the first predicted vector comprises one or more values for the one or more output variables, obtaining a desired predicted vector which comprises one or more desired values for the one or more output variables, wherein the desired values are different from the values of the first predicted vector, using the database to determine a modification of the one or more input values of the first input vector, to obtain a modified first input vector, wherein the machine learning model generates, based on the modified first input vector, an output vector matching the desired predicted vector according to a matching criterion.

In accordance with certain aspects of the presently disclosed subject matter, there is provided a system comprising a processor and memory circuitry (PMC) configured to perform operations as described with reference to the method above.

In accordance with certain aspects of the presently disclosed subject matter, there is provided a non-transitory storage device readable by a machine, tangibly embodying a program of instructions executable by the machine to perform operations as described with reference to the method above.

In accordance with certain aspects of the presently disclosed subject matter, there is provided a database informative of a machine learning model, wherein the machine learning model is associated with a set of data points, informative of a set of input vectors and of a set of predicted vectors, wherein each input vector of the set of input vectors has been used to train the machine learning model, wherein each given data point of the set of data points is associated with a given input vector of the set of input vectors, a given predicted vector of the set of predicted vectors, wherein the given predicted vector has been generated by the machine learning model using the given input vector, wherein the database is informative of a plurality of nodes comprising terminal nodes, wherein each given terminal node is associated with a plurality of data points of the set of data points, one or more coefficients defining a function, wherein the function fits a relationship between a plurality of input vectors of the plurality of data points of the given terminal node, and a plurality of predicted vectors of the plurality of data points of the given terminal node, with a quality meeting an accuracy criterion, wherein the database is usable to generate data informative of the machine learning model.

In addition to the above features, the database according to this aspect of the presently disclosed subject matter can optionally comprise one or more of features (xliv) to (lxi) below, in any technically possible combination or permutation:
xliv. at least one terminal node is further associated with one or more data points, each of these data points including an input vector which have not been used to train the machine learning model and a predicted vector generated by the machine learning model using the input vector;
xlv. each given terminal node is associated with a first set of boundaries B_{terminal_node_input} defining boundaries of a space in which all of the plurality of input vectors of all data points associated with the given terminal node are located;
xlvi. for a function of at least one terminal node, each given input variable is associated with data D_{stat_sign} informative of a statistical significance of the input variable;
xlvii. the plurality of nodes includes non-terminal nodes and terminal nodes, wherein at least one non-terminal node is linked to one or more child nodes, each child node being either a non-terminal node or a terminal node, said at least one non-terminal node being associated with a first set of boundaries B_{node_input} defining boundaries of a space in which all of the plurality of input vectors of all data points of said at least one or more child nodes are located;
xlviii. any data point including an input vector of the set of input vectors and a corresponding predicted vector of the set of predicted vectors is associated with a single terminal node of the database;
xlix. the plurality of nodes is arranged in hierarchical levels Lᵢ, with i from 1 to N, wherein each node of level Lⱼ is linked to a parent node of level Lⱼ₋₁, with j from 2 to N, wherein each node is associated with a first set of boundaries B_{node_input} defining boundaries of a space including input vectors of all data points associated with this node, wherein, for each given node linked to a parent node, a space defined by the first set of boundaries of the given node is included within the space defined by the first set of boundaries of the parent node;
l. each input vector is informative of M input variables, wherein the database includes, for at least one terminal node, data D_{certainty} informative of the certainty of the machine learning model associated with the terminal node, wherein D_{certainty} is obtained using a number N₁ of data points associated with the terminal node which include an input vector which has been used to train the machine learning model, and M;
li. the database is suitable for determining data informative of a quality of the training of the machine learning model;
lii. the database is suitable for determining a certainty of the machine learning model in its prediction;
liii. the database is suitable for determining a certainty of a prediction generated by the machine learning model depending on a range of values of input vectors fed to the machine learning model;
liv. the database is suitable for providing a recommendation of whether the machine learning model has to be retrained;
lv. the database is suitable for providing a recommendation on a range of values of input vectors for which the machine learning model has to be retrained;
lvi. the database is suitable for determining one or more input variables of the input vectors which most impact a prediction generated by the machine learning model;
lvii. the database is suitable for determining a change in one or more values of a given input vector to obtain a prediction, by the machine learning model, which matches a desired predicted vector;
lviii. the database is suitable for a given input vector, estimating a prediction which would have been generated by the machine learning model using this given input vector;
lix. the database is suitable for determining data informative of a bias in a prediction of the machine learning model;
lx. the database is generated using one or more of the methods described above; and
lxi. the database is used according to one or more of the methods described above.

According to some embodiments, the proposed solution provides a breakthrough in the field of computer-related technology, and in particular, in the field of computer-implemented machine learning models (supervised learning).

According to some embodiments, the proposed solution enables to automatically understand whether a machine learning model has been adequately trained.

According to some embodiments, the proposed solution enables to automatically understand in which areas of the input values the machine learning model is less accurate (or more accurate) in its prediction.

According to some embodiments, the proposed solution enables to automatically assess the certainty of the machine learning model in its prediction.

According to some embodiments, the proposed solution can indicate for which input vector the machine learning model tends to underperform, or to be less accurate.

According to some embodiments, the proposed solution enables to automatically point out which data should be used to retrain the machine learning model, thereby improving efficiency of the training and performance of the trained machine learning model.

According to some embodiments, the proposed solution enables to build a database which can be used to determine, based on an input vector, predicted values, in a quicker way than the machine learning model itself. In some embodiments, the prediction generated using the database is more accurate than the machine learning model itself.

According to some embodiments, the proposed solution enables a user to understand which modification should be performed to an input vector to obtain a desired predicted vector by the machine learning model. According to some embodiments, the proposed solution indicates the most optimal modification (e.g., which requires the smallest changes in the input vector) to be applied to the input vector in order to obtain the desired predicted vector.

According to some embodiments, the proposed solution generates a database modelling the behavior of the machine learning model, wherein the database is more flexible and is more simple to query than the machine learning model.

According to some embodiments, the proposed solution can compare the performance of two machine learning models, and can compare the performance depending on the input values fed to the two machine learning models.

According to some embodiments, the proposed solution can compare the performance of a machine learning model before a retraining of the machine learning model and after a retraining of the machine learning model.

According to some embodiments, the proposed solution can indicate which features of the input vector have more impact on the output generated by the machine learning model than other features of the input vector.

According to some embodiments, the proposed solution can indicate whether there is a bias in the prediction of the machine learning model.

### BRIEF DESCRIPTION OF THE DRAWINGS

In order to understand the invention and to see how it can be carried out in practice, embodiments will be described, by way of non-limiting examples, with reference to the accompanying drawings, in which:

FIG. 1A illustrates an embodiment of a system which can be used to perform one or more of the methods described hereinafter;

FIG. 1B illustrates a training set and labels used to train a machine learning model;

FIG. 1C illustrates a non-limitative example of an input vector which can be fed to the machine learning model;

FIG. 1D illustrates a non-limitative example of a predicted vector which can be generated by the machine learning model;

FIG. 1E illustrates a non-limitative example of sets of data points which can be used to build a database informative of a machine learning model;

FIG. 1F illustrates non-limitative examples of a structure of data points;

FIG. 2A illustrates an embodiment of a method of generating a database informative of a machine learning model;

FIG. 3A illustrates an embodiment of a database informative of a machine learning model;

FIG. 3B illustrates an example of terminal nodes of a database informative of a machine learning model;

FIG. 3C illustrates an example of boundaries of input vectors of data points associated with a terminal node of a database informative of a machine learning model;

FIG. 3D illustrates an example of a function fitting a relationship between input vectors and predicted vectors of data points associated with a terminal node of a database informative of a machine learning model;

FIG. 3E illustrates an example of a non-terminal node of a database informative of a machine learning model;

FIG. 3F illustrates an example of a split of a parent node into child nodes of a database informative of a machine learning model;

FIG. 4 illustrates a particular embodiment of the method of FIG. 2A;

FIG. 5 illustrates an example of a relationship between input vectors and predicted vectors for which it is not possible to accurately fit a regression function;

FIG. 6 illustrates another example of a relationship between input vectors and predicted vectors in a three-dimensional space;

FIG. 7 illustrates an example of a split of a parent node into child nodes;

FIG. 8 illustrates another example of a split of a parent node into child nodes;

FIG. 9 illustrates a split of a non-linear function of a machine learning model into sub-areas, wherein each sub-area can be modelled by a regression function;

FIG. 10A illustrates an embodiment of a method of generating additional input vectors and corresponding predicted vectors, wherein the additional input vectors have not been used during the training of the machine learning model;

FIG. 10B illustrates an example of the method of FIG. 10A;

FIG. 11 illustrates an example of a terminal node of a database informative of a machine learning model;

FIG. 12A illustrates an embodiment of a method of determining a terminal node in which an input vector is located;

FIGS. 12B and 12C illustrate examples of the method of FIG. 12A;

FIG. 13 illustrates an embodiment of a method of determining an impact of input variables on a prediction generated by the machine learning model;

FIG. 14 illustrates an embodiment of a method of determining whether the machine learning model is biased in its prediction;

FIG. 15A illustrates an embodiment of a method of using the database to generate a prediction, instead of querying the machine learning model itself,

FIG. 15B illustrates an example of the method of FIG. 15A;

FIG. 16A illustrates an example of uncertainty of a machine learning model;

FIG. 16B illustrates an embodiment of a method of determining certainty of a machine learning model;

FIG. 16C illustrates an embodiment of another method of determining certainty of a machine learning model;

FIG. 17A illustrates an embodiment of a method of comparing a first machine learning model with a second machine learning model, which uses a first database informative of the first machine learning model and a second database informative of the second machine learning model;

FIG. 17B illustrates an example of the method of FIG. 17A;

FIG. 18A illustrates an embodiment of the method of FIG. 17A;

FIG. 18B illustrates an example of the method of FIG. 18A;

FIG. 18C illustrates various applications of the method of FIG. 18B;

FIG. 19A illustrates an example of modifying an input vector informative of a patient, to generate a desired prediction by the machine learning model;

FIG. 19B illustrates an embodiment of a method of modifying an input vector to generate a desired prediction by the machine learning model; and

FIG. 19C illustrates a particular embodiment of the method of FIG. 19B.

### DETAILED DESCRIPTION

In the following detailed description, numerous specific details are set forth in order to provide a thorough understanding of the invention. However, it will be understood by those skilled in the art that the presently disclosed subject matter may be practiced without these specific details. In other instances, well-known methods have not been described in detail so as not to obscure the presently disclosed subject matter.

Unless specifically stated otherwise, as apparent from the following discussions, it is appreciated that throughout the specification discussions utilizing terms such as “obtaining”, “using”, “generating”, “determining”, “associating”, “storing”, “training”, “providing”, “estimating” or the like, refer to the action(s) and/or process(es) of a computer that manipulates and/or transforms data into other data, said data represented as physical, such as electronic, quantities and/or said data representing the physical objects.

The terms “computer”, “computer device”, and “computerized device” should be expansively construed to include any kind of hardware-based electronic device with a data processing circuitry (e.g., digital signal processor (DSP), a GPU, a TPU, a field programmable gate array (FPGA), an application specific integrated circuit (ASIC), microcontroller, microprocessor etc.). The processing circuitry can comprise, for example, one or more processors operatively connected to computer memory, loaded with executable instructions for executing operations, as further described below. The processing circuitry encompasses a single processor or multiple processors, which may be located in the same geographical zone, or may, at least partially, be located in different zones, and may be able to communicate together.

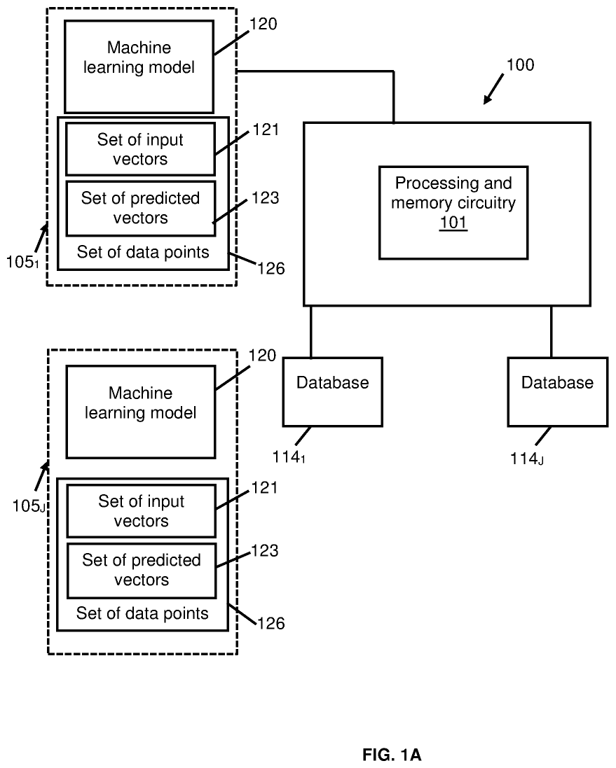

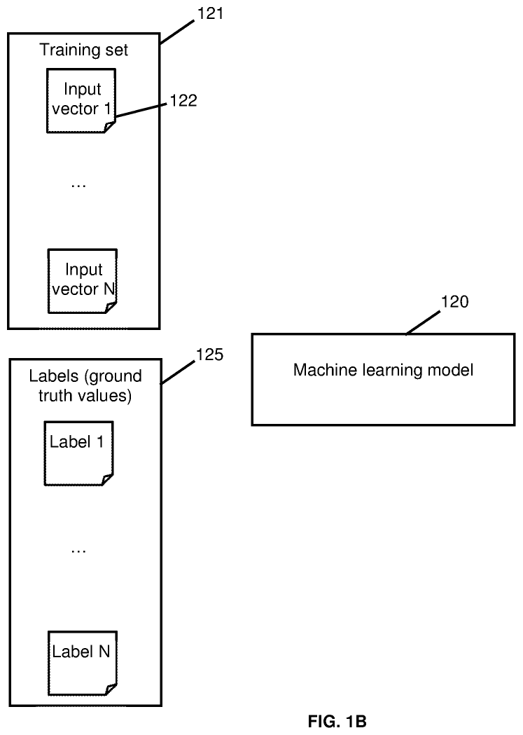

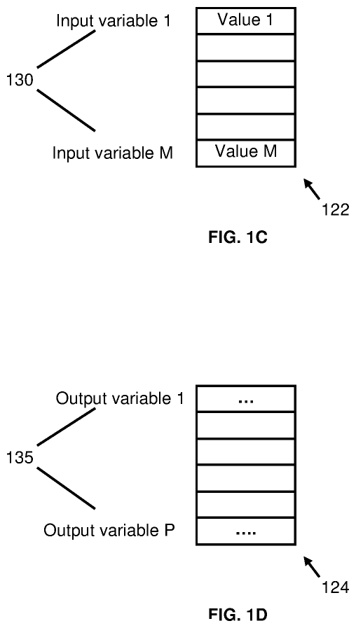

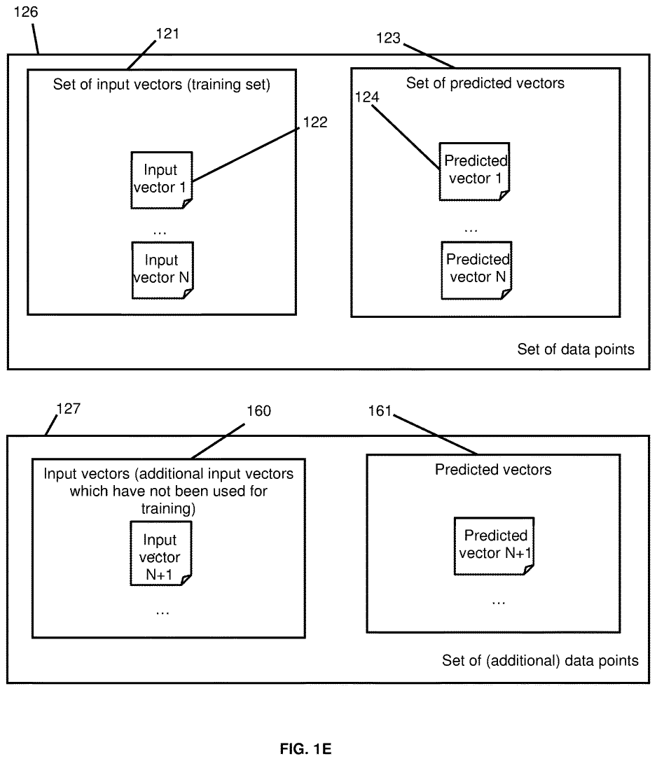

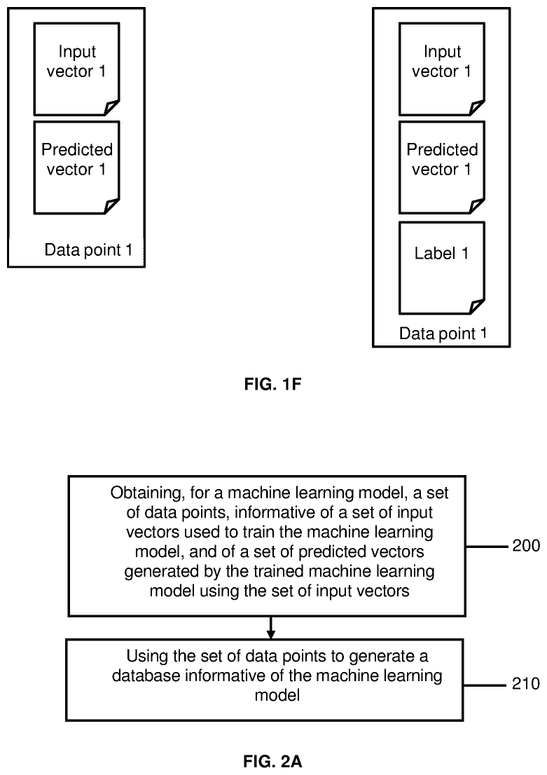

Attention is now drawn to FIG. 1A, which illustrates an embodiment of a computerized system 100 which can be used to perform one or more of the methods described hereinafter. As shown, system 100 can comprise a processor and memory circuitry 101 (PMC), comprising at least one (or more) processor, and at least one (or more) memory. The one or more processors and the one or more memories are not depicted separately. The one or more processors of PMC 101 can be configured to, either separately, or in any appropriate combination, execute operations in accordance with computer-readable instructions implemented on a non-transitory computer-readable memory comprised in the PMC 101.

In particular, PMC 101 is configured to provide all processing necessary for performing the methods described in FIGS. 2A, 4, 10A, 12A, 13, 14, 15A, 16B, 16C, 17A, 18A, 18C, and 19B.

It is to be noted that while the present disclosure refers to the PMC 101 being configured to perform various functionalities and/or operations, the functionalities/operations can be performed by the one or more processors in PMC 101 in various ways. By way of example, the operations described hereinafter can be performed by a specific processor, or by a combination of processors. The operations described hereinafter can thus be performed by respective processors (or processor combinations) in the PMC 101, while, optionally, at least some of these operations may be performed by the same processor. The present disclosure should not be limited to be construed as one single processor always performing all the operations.

In embodiments of the presently disclosed subject matter, fewer, more, and/or different stages than those shown in the methods of FIGS. 2A, 4, 10A, 12A, 13, 14, 15A, 16B, 16C, 17A, 18A, 18C, and 19B may be executed. In embodiments of the presently disclosed subject matter, one or more stages illustrated in the methods of FIGS. 2A, 4, 10A, 12A, 13, 14, 15A, 16B, 16C, 17A, 18A, 18C, and 19B may be executed in a different order, and/or one or more groups of stages may be executed simultaneously.

As explained with reference to FIG. 1B, a machine learning model 120 is a model which is trained to generate, based on at least one input vector, a predicted vector. In particular, the machine learning model 120 can be a machine learning model 120 which has been trained using supervised learning (also called “supervised machine learning model 120”). Supervised learning can include also semi-supervised learning. According to some embodiments, the machine learning model 120 can include any type of supervised learning model, including ensembles of models.

A list of instructions (e.g., an executable code/executable program) stored in a memory can encode operation of the machine learning model 120 (e.g., deep neural network—this is not limitative).

In particular, the instructions are such that, when executed by a PMC (such as PMC 101), they cause the PMC to provide, for an input vector, a predicted vector.

An example of a machine learning model is a neural network (e.g., deep neural network), which can include one or more layers.

By way of non-limiting example, the layers of the machine learning model 120 can be organized in accordance with Convolutional Neural Network (CNN) architecture, Recurrent Neural Network architecture, Recursive Neural Networks architecture, Generative Adversarial Network (GAN) architecture, or otherwise. Optionally, at least some of the layers can be organized in a plurality of DNN sub-networks. Each layer of the DNN can include multiple basic computational elements (CE), typically referred to in the art as dimensions, neurons, or nodes.

Training of the machine learning model 120 can include any adapted supervised or semi-supervised training method (e.g., Backpropagation, etc.).

FIG. 1B illustrates schematically the training of the machine learning model 120. The training of the machine learning model 120 includes using a set 121 of input vectors 122.

As depicted in FIG. 1C, each input vector includes, for one or more input variables 130 (also called features), one or more corresponding values.

For example, assume that the machine learning model 120 is trained to predict, based on medical data informative of a patient (e.g., weight, size, age, cholesterol level), the probability that the patient can suffer from a certain disease.

The input variables can include in this case the weight (first input variable), the size (second input variable), the age (third input variable) and the cholesterol level (fourth input variable). For each input variable informative of a given patient, a corresponding value is stored in the input vector 122 for this specific patient.

Note that in some embodiments, the input vector can include a single input variable (M=1).

Each input variable (feature) can be viewed as an individual measurable property or a characteristic of a phenomenon.

The machine learning model 120 uses the input vectors 122 and ground truth values 125 (also called labels) to adjust its weights.

Once the machine learning model 120 has been trained, it is possible to feed again each input vector 122 to the trained machine learning model 120 in order to obtain a corresponding predicted vector 124. As a consequence, a set 123 of predicted vectors 124 is obtained.

Each predicted vector includes, for one or more output variables 135 (also called target variables), a corresponding value.

Note that in some embodiments, the predicted vector 124 can include a single output variable (P=1).

For example, assume that the machine learning model 120 is trained to predict, for a production plant, the probability that a given apparatus will encounter a breakdown, and the type of breakdown, based on various parameters measured by sensors of the given apparatus. The first output variable is, in this case, the breakdown probability, and the second output variable is, in this case, the type of breakdown.

For each output variable of the predicted vector 124 determined for the given apparatus based on a given input vector 122, a corresponding value is stored in the predicted vector 124.

A set 126 of data points is therefore obtained, wherein each data point (see left part of FIG. 1F) is associated with a given input vector 122 and a given predicted vector 124 generated by the (trained) machine learning model using the given input vector 122. Note that for each data point, it is possible to store the input vector and the predicted vector in the same vector. In some embodiments, each data point is further associated with the label corresponding to the given input vector 122 (as depicted in the right part of FIG. 1F).

As illustrated in FIG. 1A, the computerized system 100 is operative to receive data 1051 including a trained machine learning model 120 (the computerized system 100 can receive the instructions encoding operation of the trained machine learning model 120, stored e.g., in a memory), a set 121 of input vectors (used to train the machine learning model 120), and a set 123 of predicted vectors (generated by the trained machine learning model 120 based on the set 121 of input vectors).

As visible in FIG. 1E, in some embodiments, a set of (additional) input vectors 160 can be obtained or generated by the computerized system 100. The additional input vectors 160 differ from the input vectors 122 in that these additional input vectors 160 have not been used to train the machine learning model 120.

For each additional input vector 160 (which has not been used to train the machine learning model 120), a corresponding additional predicted vector 161 is generated by the (trained) machine learning model 120. The additional predicted vector 161 can be obtained by feeding the input vector 160 to the trained machine learning model 120 and storing the output of the trained machine learning model 120 as the predicted vector 161.

As a consequence, a set 127 of (additional) data points is obtained. Each data point of the set 127 is associated with a given additional input vector 160 (which has not been used to train the machine learning model 120) and a given additional predicted vector 161 (output by the trained machine learning model 120 using the given additional input vector 160). The structure of each data point of the set 127 corresponds e.g., to the structure depicted in the left part of FIG. 1F (since the data points of the set 127 do not include any label).

Note that the term “vector” (used for the input vector and/or the predicted vector) includes any data structure which stores one or more values for one or more variables (this can include also a matrix, or other adapted data structures).

As further explained hereinafter, the system 100 is operative to generate, for each trained machine learning model (associated with a set 121 of input vectors and a set 123 of predicted vectors—see references 1501 to 150), a database (see 1141 to 114a) informative of this trained machine learning model. Therefore, for different trained machine learning models (which differ by their training set and/or by their implementation), it is expected to obtain a different database.

Attention is now drawn to FIG. 2.

In various technical fields (e.g., science, medicine, business, industry, etc.), trained machine learning models are used. It is advantageous for the users to obtain various factors regarding these trained machine learning models.

The output provided by the trained machine learning model can have critical consequences (e.g., medical decision, business decision, etc.) and it should therefore be ensured that the output is accurate (and with a high certainty).

According to some embodiments, it is advantageous to assess whether the machine learning model has been properly trained. Indeed, the machine learning model attempts to model a phenomenon (which links input variables to output variables) based on a training set, which includes only a limited number of observations of this phenomenon. This raises the question whether the trained machine learning model is capable of modelling accurately the phenomenon, or whether it should be retrained. In some cases, the machine learning model may even be biased in its prediction.

If it appears that the machine learning model has to be retrained, the user (and/or a system using the machine learning model) may wish to understand for which areas of the phenomenon the machine learning model underperforms and should be retrained, in order to provide a more efficient and focused retraining of the machine learning model.

According to some embodiments, the machine learning model can be a complex model, which therefore requires a considerable computational effort to generate a prediction (with a large time response). It can be beneficial to provide a prediction which requires less computational effort, and with a smaller time response.

According to some embodiments, the machine learning model generates a prediction based on a given input vector (for example, a risk of contracting a given disease based on the medical file of a patient) and it is advantageous to understand how the given input vector can be modified in order to obtain a desired prediction (for example, the patient/healthcare practitioner wishes to ascertain which medical parameters should be modified to reduce the probability of contracting the given disease).

FIG. 2 illustrates a method of generating a database, which is usable to generate data informative of a trained machine learning model. In some embodiments, this database can be used to solve one or more of the technical problems mentioned above. Note that this is not limitative and different and/or additional usage of this database can be made.

Assume that a trained machine learning model is associated with a set of data points (see reference 126 in FIG. 1E). The set of data points is informative of a set of input vectors (as explained above, the set of input vectors has been used to train the machine learning model), as well as of a set of predicted vectors (generated by the trained machine learning model in response to the set of input vectors).

The method of FIG. 2A includes (operations 200) obtaining the set 126 of data points associated with the machine learning model 120.

The method of FIG. 2A further includes (operation 210) using the set 126 of data points to generate a database informative of the machine learning model 120. In particular, the database is informative of nodes, which include terminal nodes. Note that in some embodiments, building of the database may include enriching the set of data points with an additional set 127 of data points.

The representation of the database using nodes can rely on various implementations, such as a graph representation, a tree representation, a representation which includes files and directories, etc.

Each terminal node is associated with a fraction of the set 126 of data points. In addition, if necessary, one or more of the terminal nodes can be associated with data points of the set 127 of data points. Each data point of the set 126 (or 127) of data points belongs to a single terminal node of the database. Therefore, the data points of each terminal node differ from the data points of the other terminal nodes of the database. In other words, there is no overlap between the terminal nodes with respect to the data points.

In addition, each given terminal node is associated with one or more coefficients, defining a function (as mentioned hereinafter, this function can be obtained using a regression analysis). The function fits a relationship between the plurality of input vectors of the plurality of data points of the given terminal node and the plurality of predicted vectors of the plurality of data points of the given terminal node with a quality (also called goodness) meeting an accuracy criterion. For example, in a simple non-limitative example in which each input vector is informative of a single input variable X, and each predicted vector is informative of a single output variable y, the function (y=AX+B) can be an affine function (slope) with two coefficients (coefficient A and coefficient B, also called intercept B).

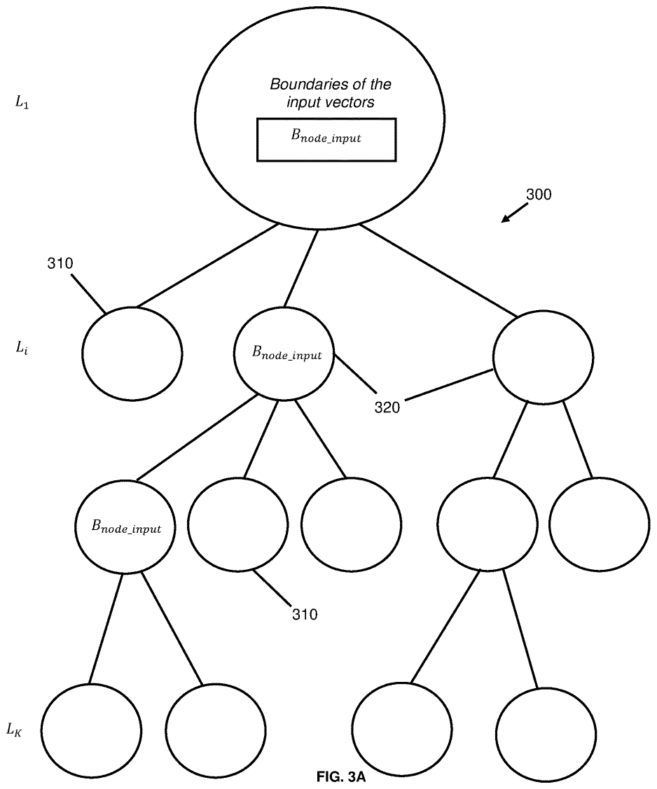

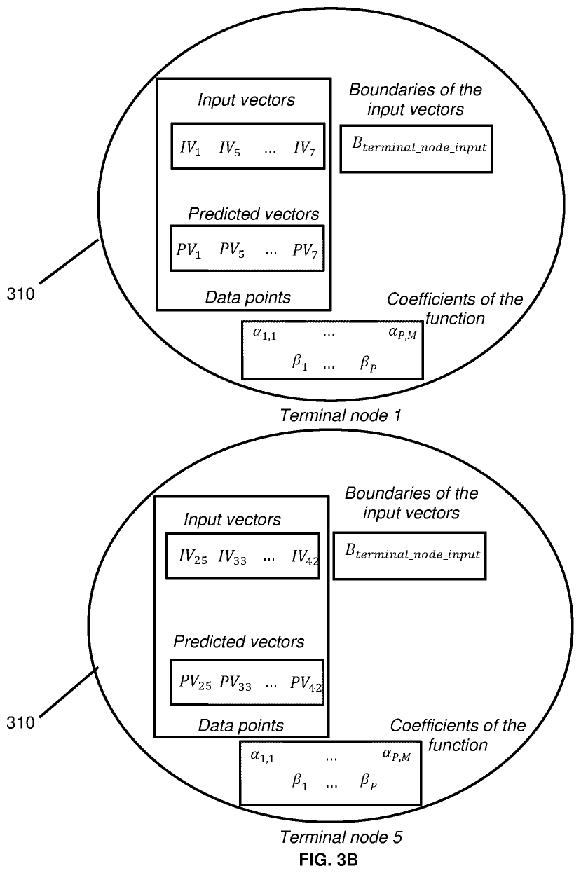

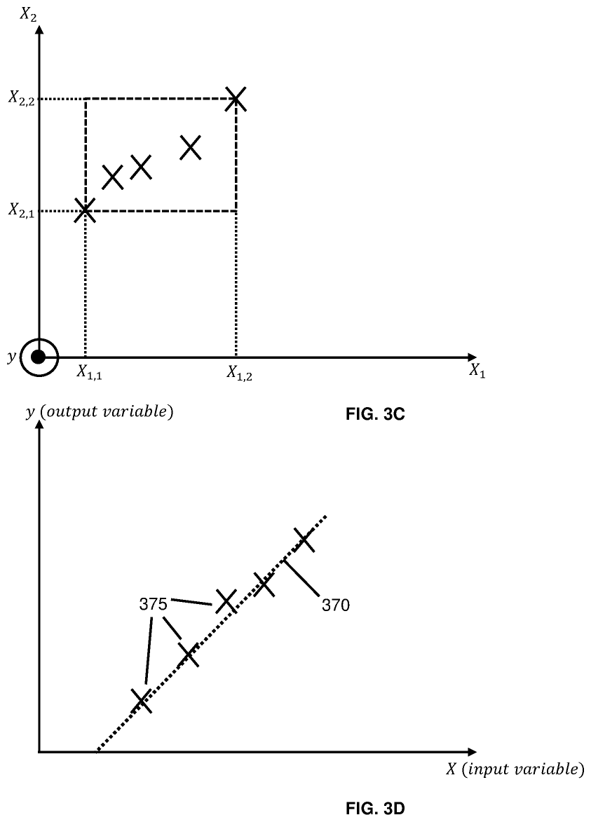

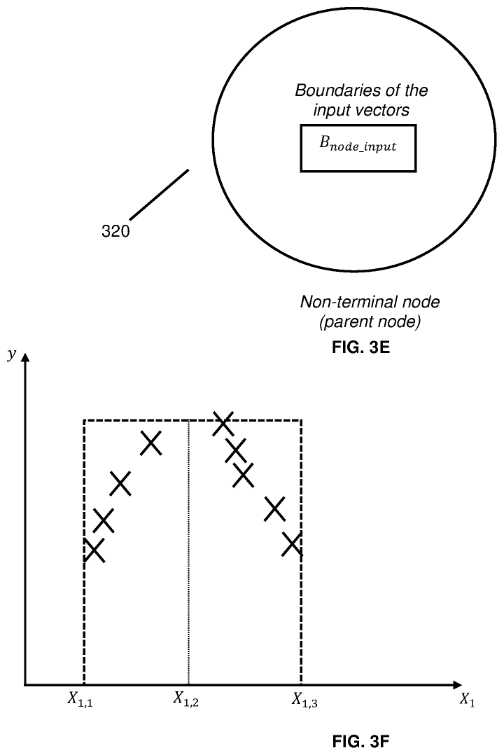

A non-limitative example of a database 300 is illustrated in FIG. 3A. The database 300 is informative of a plurality of nodes (also called vertices).

In particular, the plurality of nodes is arranged in hierarchical levels (also called tree or graph architecture). In the example of FIG. 3A, the database 300 includes hierarchical levels L₁ to L_{K}.

Some of the nodes of the database 300 are terminal nodes 310 (also called “end-nodes”, or “leaves”). Terminal nodes 310 are the nodes which do not have any children nodes in the database 300.

FIG. 3B illustrates examples of terminal nodes 310 of a database. In some embodiments, after building of the database 300, it is possible to store only the terminal nodes 310. This is however not mandatory, and in some embodiments, it is possible to store all or most of the nodes generated during the building of the database 300. Note that when querying the database, it is more computationally efficient to keep all or most of the nodes of the database 300, than keeping only the terminal nodes of the database 300.

As visible in FIG. 3B, each terminal node 310 is associated with a plurality of data points.

At least some of the data points each include an input vector 122 of the set 121 of input vectors and a predicted vector 124 of the set of 123 of predicted vectors (the predicted vector 124 has been generated by the machine learning model 120 using the input vector 122).

For example, in FIG. 3B, one of the data points of “terminal node 1” includes an input vector IV₂₅ and a predicted vector PV₂₅.

In some embodiments in which the set 127 of data points has been generated (see FIG. 1E), the terminal node 310 can be further associated with one or more data points each including an input vector 160 (which has not been used for the training of the machine learning model 120) and an additional predicted vector 161 (generated by the machine learning model 120 using the input vector 160). Each terminal node 310 can store the plurality of data points and/or can store a pointer enabling retrieval of this plurality of data points.

Assume for example that the set 126 of data points includes Q data points. Generally, each terminal node 310 is associated with a limited fraction (limited subset) of the Q data points of the set 126. In other words, each terminal node 310 is associated with Q* data points, with Q*<Q. Note that in some specific embodiments, it can occur that Q*=Q (in this case there is a single node, which corresponds both to the root node and to the single terminal node).

Assume in another example that the database has been built using a set 126 of data points including Q data points and a set 127 of data points including Q₁ data points.

Generally, each terminal node 310 is associated with a limited fraction (limited subset) of the Q+Q₁ data points of the sets 126 and 127 of data points. In other words, each terminal node 310 is associated with Q*data points, with Q*<Q+Q₁. Note that in some specific embodiments, it can occur that Q*=Q+Q₁.

According to some embodiments, each terminal node 310 can store (or be associated with) a first set of boundaries B_{terminal_node_input} defining boundaries of a space in which all of the plurality of input vectors of the data points associated with the given terminal node are located.

A non-limitative example is depicted in FIG. 3C. Assume for example that each input vector is informative of a first input variable X₁ (e.g., the height of a patient) and a second input variable X₂ (e.g., the weight of the patient). FIG. 3C illustrates the distribution of the input vectors associated with a given terminal node. In this example, B_{terminal_node_input} stores the range [X_{1,1}; X_{1,2}] for the first input variable X₁ and the range [X_{2,1}; X_{2,2}] for the second input variable X₂.

Note that the example of FIG. 3C can be extended to a multi-dimensional space, in which each input vector is informative of M input variables, with M≥2.

In other words, for a given terminal node, B_{terminal_node_input} stores, for each input variable, the minimal value and the maximal value among all input vectors of all data points of this given terminal node.

In some embodiments, each terminal node can store a list of data points associated with this terminal node (or can store a pointer to these data points).

As visible in FIG. 3B, each terminal node 310 is associated with one or more coefficients defining a function.

As mentioned above, each data point of each terminal node 310 is associated with some input vectors (informative of one or more input variables X₁ to X_{M}, with M≥1) and some predicted vectors (informative of one or more output variables Y₁ to Y_{P}, with P≥1). The function fits (models) a relationship between the plurality of input vectors of the given terminal node 310 and the plurality of predicted vectors of the given terminal node 310. As explained hereinafter, this function can be a regression function, obtained using a regression analysis.

According to some embodiments, the function can be expressed using a linear expression (linear function) as follows (this is not limitative).

$$[ \begin{matrix}{y}_{1} \\ ⋮ \\ {y}_{P}\end{matrix} ] = [ \begin{matrix}{α}_{1 , 1} & … & {α}_{1 , M} \\ ⋮ & ⋱ & ⋮ \\ {α}_{1 , P} & … & {α}_{P , M}\end{matrix} ] [ \begin{matrix}{X}_{1} \\ ⋮ \\ {X}_{M}\end{matrix} ] + [ \begin{matrix}{β}_{1} \\ ⋮ \\ {β}_{P}\end{matrix} ]$$

The coefficients α_{1,1} to α_{P,M} and β₁ to β_{P} can be stored (or associated with) in each terminal node 310.

In a simple example illustrated in FIG. 3D, in which the input vector is informative of a single input variable X, and the predicted vector is informative of a single output variable y, the function can be an affine function 370 (slope) which fits the relationship between the single input variable and the single output variable, using the values 375 of the input vectors and the predicted vectors of the data points of this terminal node.

As explained hereinafter, the terminal nodes differ from the non-terminal nodes in that this fitting between the function and the relationship is performed with a quality meeting an accuracy criterion. In the simple example above, this can mean that a statistical measure of the fitting of the affine function with the data points (each data point has an abscissa which is the value of the input vector, and an ordinate which is the value of the corresponding predicted vector) indicates an accurate fitting.

Non-terminal nodes 320 (also called parent nodes) are nodes which have at least one child node (in some embodiments, two or more child nodes) in the database 300. An example is illustrated in FIG. 3E.

Each node of the database 300 is associated with a first set of boundaries B_{node_input} defining boundaries of a space including a subset of the input vectors of the set 121 of input vectors (and, optionally, of the set 160 of input vectors) of all data points of this node. In some embodiments, the node can also store the data points used to build this node, or a pointer to these data points.

The relationship between a parent node and the child nodes can be as follows: the space defined by the first set of boundaries of the given node is included within the (larger) space defined by the first set of boundaries of the parent node.

A simple example is illustrated in FIG. 3F. Assume that each input vector includes a single input variable X₁ corresponding to the weight of people.

Assume that a parent node is associated with a first set of boundaries

$${B}_{node \_ input} = [ {X}_{1 , 1} ; {X}_{1 , 3} ] = [ 40 kg ; 80 kg ] .$$

According to some embodiments, the first set of boundaries of the parent node can be split into two (note that this is not limitative, and the split can be performed using a different number of child nodes and/or using a split at a different splitting value of the first set of boundaries).

A first child node is associated with a first set of boundaries B_{node_input}=[X_{1,1};X_{1,2}][40 kg; 60 kg]. In other words, all data points of the parent node which include an input vector located in the range [X_{1,1}; X_{1,2}] are assigned to the first child node. The space (in this example, this is a 1D space) defined by the input vectors of this first child node is fully included with the space defined by the input vectors of the parent node.

A second child node is associated with a second set of boundaries B_{node_input}=[X_{1,2};X_{1,3}][60 kg; 80 kg]. In other words, all data points of the parent node which include an input vector located in the range [X_{1,2}; X_{1,3}] are assigned to the second child node. The space (in this example, this is a 1D space) defined by the input vectors of this second child node is fully included with the space defined by the input vectors of the parent node.

Note that this example can be generalized to a N-dimensional space.

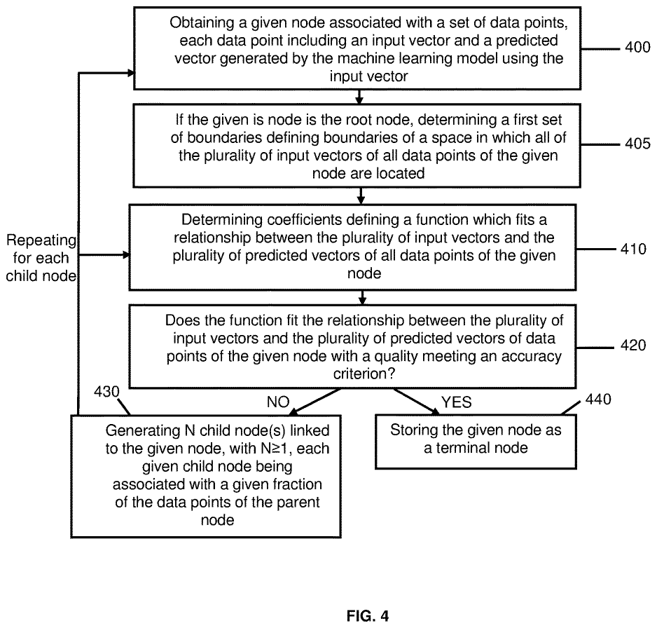

Attention is now drawn to FIG. 4, which is a particular embodiment of the method of FIG. 2A.

As visible in FIG. 4, the method can be recursive or sequential.

Assume that it is aimed at building a database informative of a given machine learning model, which has been trained using a set 121 of input vectors (training set). This set 121 of input vectors can be fed to the trained machine learning model to generate a set 123 of predicted vectors. Therefore, a set 126 of data points is obtained for this given machine learning model. Note that for input variables (features) and/or output variables (features) which are not numerical values (for example a list of symptoms of a disease), it is possible to convert this list of features into a numerical discrete non-ordered representation (each symptom receives e.g., a different predefined value).

The method includes obtaining (400) a given node associated with a plurality of data points of the set 126 of data points.

At the first iteration of the method, the given node can correspond to the root node. The root node of the database can be associated with the full set 126 of data points. Note that in some embodiments, it is possible to enrich the set 126 of data points with additional data points, which include input vectors which have not been used to train the machine learning model (this will be further discussed hereinafter).

At the first iteration of the method, in which the given node corresponds to the root node, the method includes determining (operation 405) a first set of boundaries B_{node_input} defining boundaries of a space in which all of the plurality of input vectors of all data points of the given node are located. In particular, these boundaries can define the minimal and maximal values of each input variable of the input vectors of the data points associated with the given node.

Assume for example that each input vector is informative of one or more input variables X₁ to X_{M}, with M≥1.

Operation 405 can include determining, for each input variable Xᵢ (with 1≤i≤M), the minimal value X_{i,min} and the maximal value X_{i,max} for all input vectors of all data points of the given node. This provides the first set of boundaries B_{node pred}, as indicated below:

$${B}_{node \_ input} = [ \begin{matrix}{X}_{1 , min} ; {X}_{1 , max} \\ ⋮ \\ {X}_{M , min} ; {X}_{M , max}\end{matrix} ]$$

The method of FIG. 4 further includes determining (operation 410) a function which fits (models) a relationship between the plurality of input vectors of the given terminal node and the plurality of predicted vectors of the given terminal node.

Operation 410 attempts to find coefficients of a function which fit, as best as possible, the relationship between the plurality of input vectors of the data points of the given terminal node and the plurality of predicted vectors of the data points of the given terminal node, for all data points of the given terminal node.

Operation 410 can include performing a regression analysis to determine the coefficients of the function. The regression analysis can include linear regression, logistic regression, multiclass regression, or similar methods. For example, one or more regression analysis/methods provided in the “spark.ml.regression package” can be used. This is not limitative.

In a simple example in which there is a single input variable X and a single output variable y, a regression can be performed to find coefficient A and intercept B of a function (y=AX+B) which models (as best as possible) the relationship between y and X for all input vectors and predicted vectors for all data points associated with the given node.

More generally, it can be attempted to find coefficients of a function which fits (as best as possible) the relationship between the M input variables and the P output variables for all input vectors and predicted vectors of all data points associated with the given node.

In a non-limitative example, the function can be expressed as follows using the non-limitative expression (note that this expression can be used also to model regression functions obtained using a logistic regression and/or a multiclass regression):

$$[ \begin{matrix}{y}_{1} \\ ⋮ \\ {y}_{P}\end{matrix} ] = [ \begin{matrix}{α}_{1 , 1} & … & {α}_{1 , M} \\ ⋮ & ⋱ & ⋮ \\ {α}_{1 , P} & … & {α}_{P , M}\end{matrix} ] [ \begin{matrix}{X}_{1} \\ ⋮ \\ {X}_{M}\end{matrix} ] + [ \begin{matrix}{β}_{1} \\ ⋮ \\ {β}_{P}\end{matrix} ]$$

In this example, operation 410 attempts to determine α_{1,1} to α_{P,M} and β₁ to β_{P}.

Depending on the number of input variables and output variables, the function can include e.g., an affine function, a plane, an hyperplane (hyperplane), a plurality of hyperplanes (the matrix resulting from the regression analysis defines a hyperplane of M dimensions, wherein M in the number of input variables—in case the number of predicted variables is one, there is one hyperplane of M dimensions and in case the number of predicted variables is greater than one, there is one hyperplane of M dimensions per dimension of the output variables).

The method of FIG. 4 further includes determining (operation 420) whether the function fits the relationship between the plurality of input vectors and the plurality of predicted vectors of the data points of the given node with a quality meeting an accuracy criterion.

A simple example can be used to understand operation 420. Note that although this example illustrates a simple linear regression, it is to be understood that operation 420 is not limited to this type of regression.

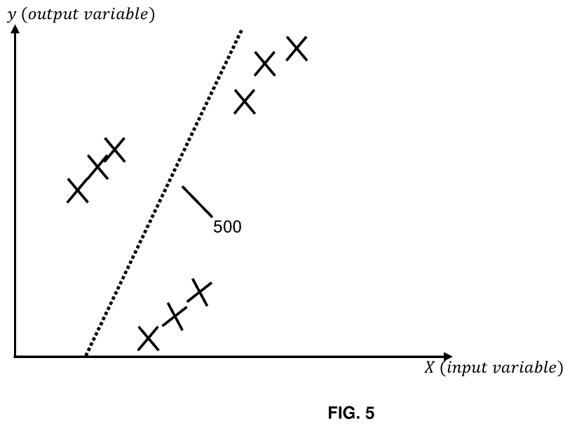

Assume for example that there is a single input variable X and a single output variable y. The distribution of the values of X and y is illustrated in FIG. 5. It has been attempted to determine a linear function 500 which fits the relationship between the values of X and the values of y. As visible in FIG. 5, the quality of the fitting of the linear function 500 has a low accuracy. As a consequence, the fitting of this relationship with a function is not accurate.

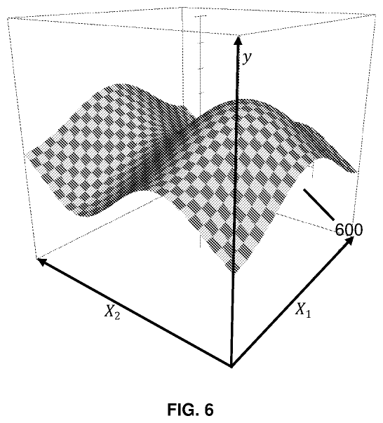

FIG. 6 illustrates another example in a three-dimensional space. Assume for example that there are two input variables X₁, X₂ and a single output variable y. The distribution of the values of X₁, X₂ and y is illustrated in FIG. 6, for the given node under analysis.

If it is attempted to fit the distribution 600 of the values of FIG. 6 with a three-dimensional plane, this will provide a fitting which is not accurate.

According to some embodiments, in order to determine whether the function fits the relationship between the plurality of input vectors and the plurality of predicted vectors of the data points of the given node with a quality meeting an accuracy criterion, a goodness-of-fit measure can be determined. In some embodiments, the value R-squared (R²) can be determined.

If the value R-squared is above (or equal to) a predefined threshold (defined by the accuracy criterion—in a non-limitative example, this threshold can be selected as equal to 0.9), then this indicates that the function fits the relationship between the plurality of input vectors and the plurality of predicted vectors of the data points of the given node with a quality meeting the accuracy criterion.

If the value R-squared is below a predefined threshold (defined by the accuracy criterion—in a non-limitative example, this threshold can be selected as equal to 0.9), then this indicates that the function does not fit the relationship between the plurality of input vectors and the plurality of predicted vectors of the data points of the given node with a quality meeting the accuracy criterion.

If operation 420 indicates that the function does not fit the relationship between the plurality of input vectors and the plurality of predicted vectors of the data points of the given node with a quality meeting the accuracy criterion, the method can include (operation 430) generating N child nodes linked to the given node, with N≥1 (or, in some embodiments, with N≥2).

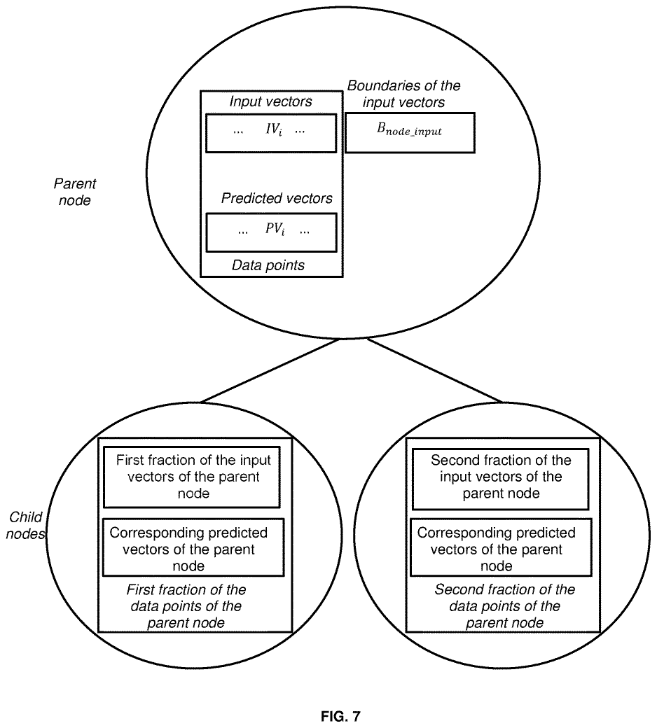

As illustrated in FIG. 7, each given child node is associated with a given fraction (limited subset, and not the whole subset) of the plurality of data points of the given node (parent node).

As a consequence, each given child node is associated with a fraction of the input vectors of the data points of the parent node, and with a fraction of the predicted vectors of the data points of the parent node (generated by the machine learning model using the fraction of the plurality of input vectors of the given node).

Generally, each given child node is associated with a fraction of the plurality of data points of the given node (parent node), which is different from the other child nodes. In other words, the initial set of data points of the parent node has been split, and each child node is associated with a limited fraction of the initial set of data points.

In some embodiments, for the same parent node, there is no overlap between the data points of a given child node with data points associated with other child nodes. In particular, according to some embodiments, for a given parent node, each pair of vectors, which includes a given input vector and a corresponding predicted vector, is associated with a single child node of this parent node (and is not associated with two child nodes or more of this parent node).

Assume that there are M input variables X₁ to X_{M} (with M≥1) and P output variables Y₁ to Y_{P} (with P≥1). In some embodiments, it can be decided to split (equally) the space defined by the input vectors of the parent node along each input variable by a predetermined factor K (e.g., by factor K=2, but this is not limitative). This provides a number of potential child nodes equal to K^{M}.

Note that it can occur that following the split, one child node receives all of the data points which include an input vector used to train the machine learning model. In this case, a single child node is created.

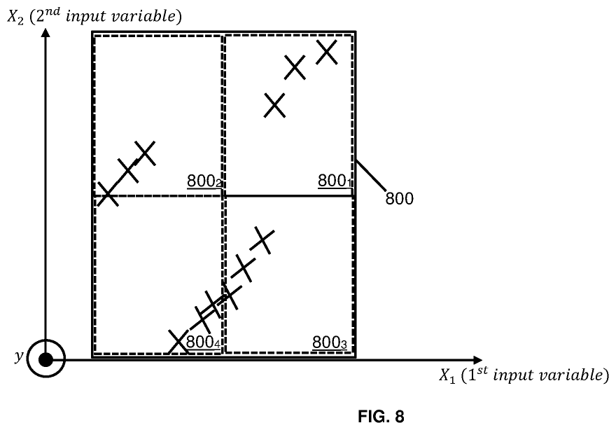

A simple example of a split of a parent node into child nodes is illustrated in FIG. 8. Assume that for example that there are two input variables X₁ and X₂. The values of the input vectors of the data points associated with the parent node are depicted by the area 800. It can be decided to split this area 800 along the first input variable X₁ by a factor of 2 and to split this area 800 along the input variable X₂ by a factor of 2.

Consequently, four child nodes are generated. Each child node is assigned with a fraction (see areas 800₁, 800₂, 800₃ and 800₄) of the input vectors (and corresponding predicted vectors), thereby receiving a fraction of the data points of the parent node.

Reverting to the method of FIG. 4, once the child nodes have been generated, the method of FIG. 4 can be repeated for each child node. In particular, for each child node, operation 410 is repeated (note that operations 405 does not need to be repeated, since the boundaries of the input vectors of the data points are known based on the split performed at operation 430). In other words, the “given node” mentioned at operation 410 is now the child node.

Although for the parent node it was not possible to determine a function which fits accurately the relationship between the input vectors and the predicted vectors of the data points of this parent node, a different conclusion may be reached for the child nodes. Indeed, each child node is now associated with a smaller subset of data points (including input vectors/predicted vectors), and therefore, it may now be possible to determine a function which accurately fits this relationship, for this smaller subset of data points.

For each child node, operation 420 is repeated. If the function fits the relationship between the plurality of input vectors and the plurality of predicted vectors of the data points of the child node with a quality meeting the accuracy criterion, then this child node is stored as a terminal node of the database (operation 440).

If the function does not fit the relationship between the plurality of input vectors and the plurality of predicted vectors of the data points of the child node with a quality meeting the accuracy criterion, then operation 430 is repeated. The child node is itself used as a parent node to generate at least one child node linked to this parent node, as explained above.

The method can be repeated until a convergence criterion is met.

In some embodiments, the convergence criterion can define that the method is repeated until a function is found for each child node.

In some embodiments, the convergence criterion can define the maximal number of iterations of the method (which, in turn, defines the depth of the tree). For example, it can be defined that the maximal depth of the tree (maximum length of any path from the root to a terminal node) cannot be larger than ten. This is not limitative.

When this maximal number of iterations has been reached, and it was not possible to find a function accurately fitting the relationship between the input vectors and the predicted vectors for the data points of these child nodes, then these child nodes are not split again.

In some embodiments, once the maximal number of iterations has been reached, these child nodes are stored as terminal nodes, although the function does not meet the fitting requirement.

In some embodiments, if a function is not found for a child node, although the number of iterations of the method has reached its maximal threshold, the method can include associating these child nodes with an indicator indicative that a relationship between the plurality of input vectors and the plurality of predicted vectors for these data points does not meet a required condition for these child nodes.

For a child node for which the function fits the relationship between the plurality of input vectors and the plurality of predicted vectors of the data points of the child node with a quality meeting the accuracy criterion, the child node is stored (operation 440) as a terminal node of the database.

As can be understood, the initial space (which included the data points informative of the input vectors used for training the machine learning model and of the corresponding predicted vectors) has been split progressively, until a function accurately fitting the relationship between the input vectors and the predicted vectors has been obtained for each sub-area of the initial space.

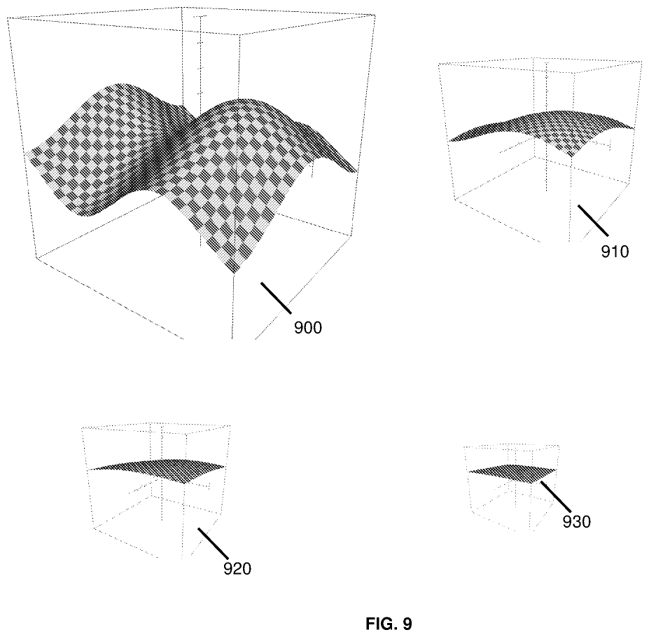

The process is illustrated schematically in FIG. 9. For the root node (see reference 900), it was not possible to find a regression function accurately fitting the relationship between the input vectors and the predicted vectors. For a child node (of the second level of the tree), the regression function fits better the relationship between the input vectors and the predicted vectors (see reference 910). For a child node (of the third level of the tree), the regression function better fits the relationship between the input vectors and the predicted vectors (see reference 920). For a child node (of the fourth level of the tree), the regression function fits the relationship between the input vectors and the predicted vectors (see reference 930) according to the accuracy criterion.

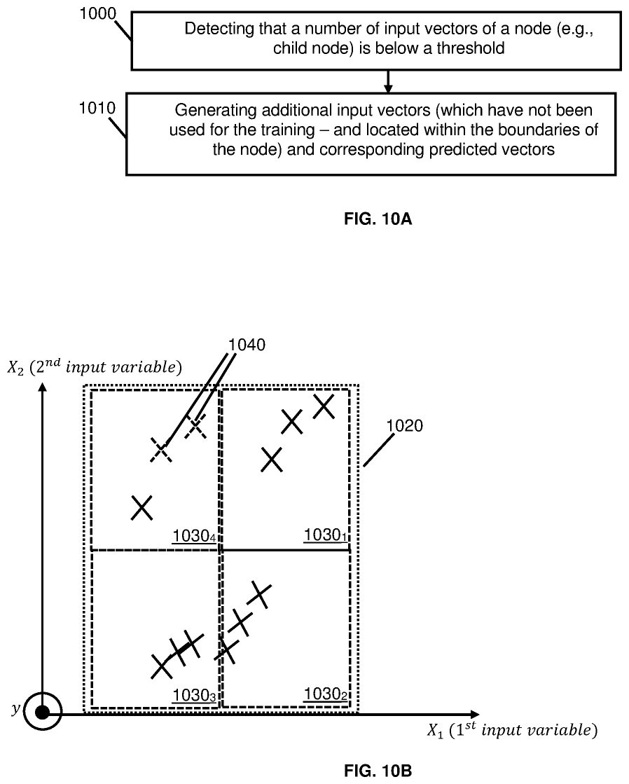

Attention is now drawn to FIG. 10A.

As mentioned above with reference to operation 430 of FIG. 4, when it is not possible to find a regression function which accurately fits the relationship between the input vectors and the predicted vectors of the data points of a given node, N child nodes are generated. Each child node is associated with a fraction of the data points of the parent node.

In some cases, it can occur that the number of data points of the parent node is small, and therefore, one or more of the child nodes do not receive enough data points. In particular, one or more child nodes may receive a number of data points informative of input vectors used to train the machine learning model which is below a threshold.

The method of FIG. 10A can include detecting (operation 1000) that a number of data points of a node (e.g., child node) is below a threshold. The threshold can be predefined and/or selected by an operator.

In this case, the method can include (see FIGS. 10A and 10B) generating (operation 1010) “artificial” data points, which include input vectors which have not been used in the training of the machine learning model. As mentioned above, each node can be associated with a first set of boundaries B_{node_input} defining boundaries of a space in which all of the plurality of input vectors of the given node are located. Input vectors which are located within B_{node_input} can be generated and fed to the observed machine learning model. As a consequence, corresponding predicted vectors are obtained. The artificial input vectors (and corresponding predicted vectors) are then associated with the node, in order to reach the required number of input vectors (and corresponding predicted vectors) for this node.

This corresponds to the set 127 of data points illustrated in FIG. 1E.

A non-limitative example is illustrated in FIG. 10B.

Assume that a parent node is associated with data points including input vectors represented by the area 1020. The parent node is split into four child nodes 10301 to 10304.

Node 10314 receives a number of data points (one in this example), which is below a threshold.

As a consequence, artificial data points including input vectors 1040 (with corresponding predicted vectors along the “y” axis in FIG. 10B) are generated, which are located within the boundaries B_{node_input} of the node 10304. The new number of data points of the node 10304 now reaches the required threshold.

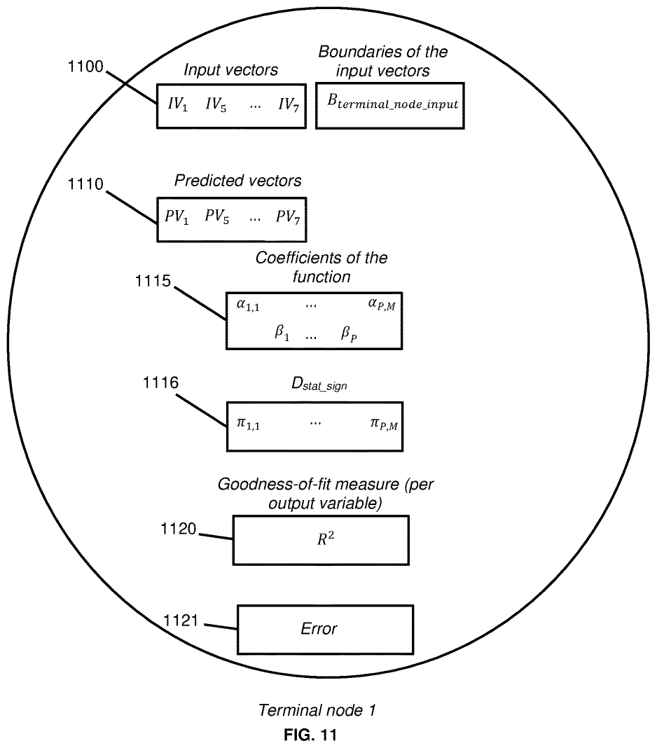

Attention is now drawn to FIG. 11.

As mentioned above, a terminal node can be associated with:
a plurality of data points, each including an input vector 1100 and a predicted vector 1110 generated by the machine learning model using the input vector 1100;
one or more coefficients 1115 defining a function, wherein the function fits a relationship between the plurality of input vectors of the given terminal node and the plurality of predicted vectors of the given terminal node with a quality meeting the accuracy criterion (in some cases in which the maximal number of layers of the database has been reached, it may occur that this function does not fit the relationship with a quality meeting the accuracy criterion).

According to some embodiments, each terminal node can be associated with additional information. In particular, each terminal node can be associated with a goodness-of-fit measure 1120, which indicates how well the function fits the relationship between the input vectors and the predicted vectors of the data points of this terminal node. Examples of the goodness-of-fit measure have been provided above. Note that if more than one output variable is present, a goodness-of-fit measure can be determined for each output variable.

As depicted in FIG. 11, in some embodiments, for each terminal node, each given input variable is associated with data D_{stat_sign} (see reference 1116) informative of a statistical significance of the input variable (in the regression function of the terminal node). According to some embodiments, D_{stat_sign} can correspond to a p-value. The p-value is often expressed as a p-value between 0 and 1. The higher the p-value, the higher the probability that the corresponding input variable does not affect the output of the function, and the lower the p-value, the higher the probability that the corresponding input variable affects the output of the function.

The higher the p-value for a given input value, the higher the probability that other input values (different from the given input value) cause the output of the function. Similarly, the lower the p-value for a given input value, the lower the probability that other input values (different from the given input value) cause the output of the function.

As a consequence, D_{stat_sign} also indicates the probability that the corresponding input variable affects the prediction generated by the machine learning model, since the function models the behaviour of the machine learning model (within a particular area of input values).

In addition to D_{stat_sign}, the magnitude (amplitude) of each coefficient of the function, associated with each given input variable, is informative of the significance (also called impact) of the given input variable on the output of function (and therefore, on the prediction of the machine learning model, since the function models the behaviour of the machine learning model).

In a simple example, the coefficient can be viewed as the “slope” of the function for the given input variable, and the p-value is the probability that this “slope” is fictitious (and caused by other input variables).

Assume for example that the input variables correspond to the educational profile of people (name of the university, type of degree, years of experience in a similar position, etc. —note that non-numerical values can be converted into numerical values), and that the output variable corresponds to the probability that the person will be adequate for a given position in a firm. A machine learning model has been trained to predict the adequacy of the person for the position, based on these input values, using a training set of data of various candidates.

The data D_{stat_sign} and/or the magnitude of the coefficients can indicate which input variables are the most critical for a person to fit, for the given position.

Note that the data D_{stat_sign} and/or the magnitude of the coefficients can differ between the different terminal nodes, and therefore, for some profiles of people, the name of the university can have the strongest impact, whereas for other profiles of people, the number of years of experience in a similar position can have the strongest impact.

According to some embodiments, each terminal node is associated with one or more errors 1121. The errors can include the error between the prediction generated by the machine learning model and the ground truth value, and/or the error between the ground truth value and the function and/or the error between the prediction and the function.

Once the database informative of the machine learning model (and in particular, informative of the training of the machine learning model) has been generated, the database can be used for various applications. This database is highly advantageous and provides to the user(s) of a computerized machine learning model an understanding of the machine learning model (and of its training) which has never been achieved in the prior art.

In some embodiments, the database can be used to determine data informative of a quality of the training of a machine learning model. As explained in the some of the embodiments, it is possible to assess whether the machine learning model has received sufficient training data to model accurately the phenomena, whether it gives the correct weight to each input variables based on the training set, whether it is biased, etc.

In some embodiments, the database can be used to generate a prediction (with a good accuracy) with a computing time which is reduced, compared to the machine learning model itself. This is due, in particular, to the fact that the database has converted the original complex multi-dimensional model into a plurality of regression functions, which can be quickly addressed in order to provide a quick response.

Various other applications of the database are described hereinafter. Note that these applications are not limitative and different/additional applications can be implemented.

For each pair including a trained machine learning algorithm with a corresponding training set (and corresponding predicted data), a different database can be generated, specifically built to model this machine learning model trained with this corresponding training set, as illustrated in FIG. 1A.

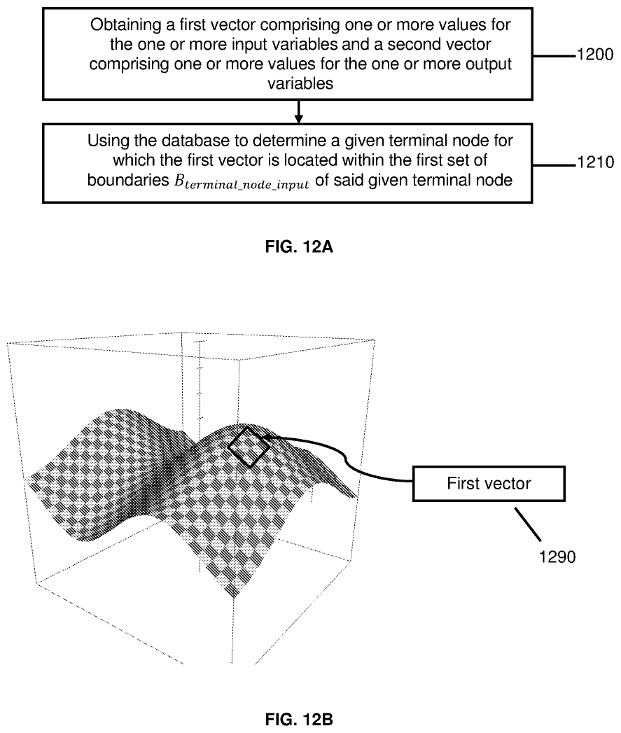

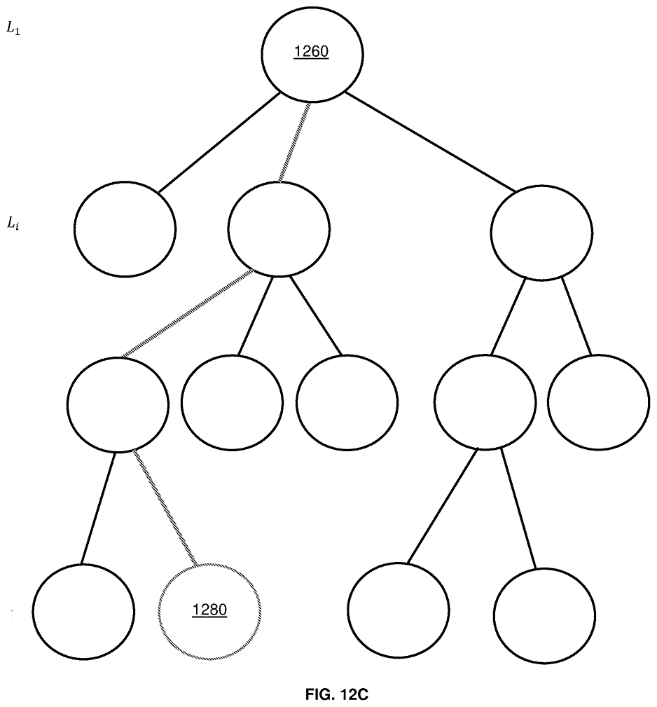

Attention is now drawn to FIG. 12A.

Assume that a database has been built (using one or more of the methods described above) informative of a given trained machine learning model. The given trained machine learning model is operative to predict, based on values of the input variables, values of the output variables.

The method of FIG. 12A includes obtaining (operation 1200) a data point including a first vector comprising one or more values for the one or more input variables, and a second vector comprising one or more values for the one or more output variables (the second vector has been generated by the machine learning model based on the first vector).

The method of FIG. 12A enables to determine a terminal node for which the first vector is located within the space of input vectors defined by this terminal node.

The method includes using (operation 1210) the database to select the terminal node for which the first vector is located within the first set of boundaries B_{terminal_node_input} of the given terminal node.

Operation 1210 can include going over the tree in a progressive manner (from the root node towards the terminal nodes), until the relevant terminal node is identified. For each node, the values of this first vector is compared to B_{node_input} of this node, in order to select the relevant node at each layer of the tree. This process is repeated until a terminal node of the database is reached.

This is shown in FIG. 12C, in which a path has been determined from the root node 1260 up to the relevant terminal node 1280.

This is also schematically illustrated in FIG. 12B. The multi-dimensional non-linear function of the machine learning model has been split into a plurality of areas, each modelled by a function, and it is attempted to find in which area 1290 the first vector is located.

Note that in some embodiments, the database includes only the terminal nodes. In this case, a sequential method is performed in which the boundaries of each terminal node are compared with the first vector to determine the relevant terminal node.

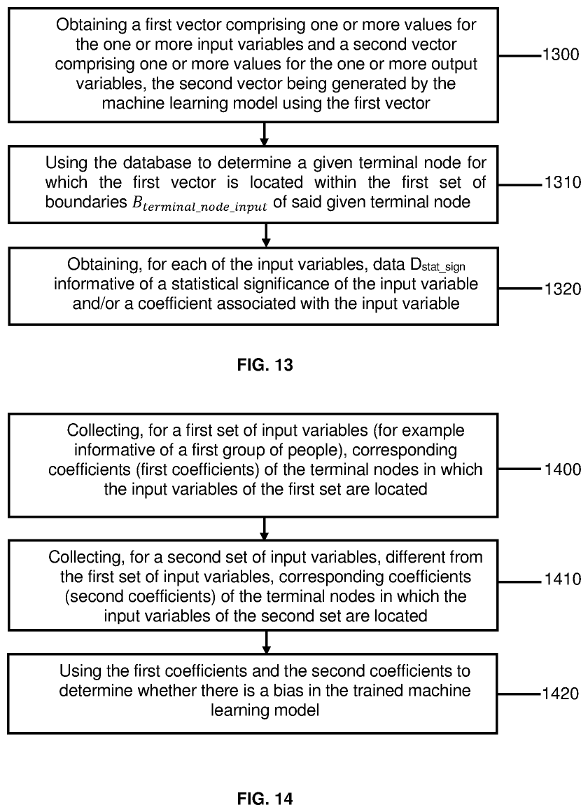

Attention is now drawn to FIG. 13.

Assume that a database (using one or more of the methods described above) informative of a given trained machine learning model has been built.

The method of FIG. 13 includes obtaining (operation 1300) a first vector comprising one or more values for the one or more input variables. In some embodiments, the method can further include feeding the first vector to the machine learning model to obtain a second vector comprising one or more values for the one or more output variables

It is now desired to understand, for this first vector, which input variables have the greatest impact on the output variables. This can be used in various technical fields.

For example, assume that the machine learning model is trained to predict, based on input variables of a device (average temperature, average pressure, age of the device, etc.), the probability that the device will encounter a failure (output variable).

Assume that the machine learning model has predicted, for a given device (defined by a first vector), that there is a high probability to encounter a failure (second vector).

It can be desired to understand which input variables of the first vector are the most significant in any decision of the machine learning model to output a high probability of failure in the second vector. Understanding of this impact can then be used to optimize maintenance, improve future design of this type of device, etc.

The method of FIG. 13 includes determining (operation 1310) a given terminal node of the database for which the first vector is located within the first set of boundaries B_{terminal_node_input} of said given terminal node. The method of FIG. 12A can be used to perform operation 1310.

The method of FIG. 13 further includes obtaining (operation 1320), for each input variable D_{stat_sign} informative of a statistical significance of the input variable (for the function of the given terminal node). Alternatively, or in addition, the method can include obtaining a magnitude of the coefficient associated with each input variable for the function associated with the given terminal node.

Continuing with the example cited above (failure prediction in a device), assume that the following coefficients are obtained: for the average temperature, a small coefficient, for the average pressure, a high coefficient, for the age of the device, a medium coefficient. It can therefore be concluded that the average temperature of the device has the greatest impact on the decision of the machine learning model to output a high probability of failure. The user can therefore take appropriate decisions, such as performing a maintenance operation to reduce the average temperature, modifying the future design of the device to decrease the average temperature, etc.

In another example, assume that a machine learning model is used by a bank to decide whether a client should be granted a loan. The input vector includes the profile of the client (age, income, gender, number of children, etc.) and the predicted vector includes the probability that the client should be granted a loan (the higher the output value of the predicted vector, the higher the probability that a positive answer should be issued by the bank).

Assume that a client with a given profile has received a negative answer. The client is interested to know which variables of his profile had the greatest impact in the negative decision taken by the machine learning model used by the bank. The method of FIG. 13 can output the one or more input variables which have the greatest impact on this negative decision. For example, the method of FIG. 13 can indicate that the age of the client had the greatest impact (because the coefficient is the largest for this input variable, for the terminal node which includes the input values of the client). In this case, the client understands that he cannot modify his profile to get a positive answer, and should therefore ask for a loan in a different bank.

These examples are not limitative and various other applications can be used.

According to some embodiments, it is possible to analyse the distribution of the coefficients. If for some of the terminal nodes, the distribution is not balanced (e.g. not Gaussian), this can indicate that the machine learning model relies more on certain input variable(s) than on other input variables to generate its prediction. This can be output to the user. It is possible to provide to the user the range of the input values (which are known from the boundaries of the terminal node) in which the machine learning model relies more on certain input variable(s) than on other input variables to generate its prediction.

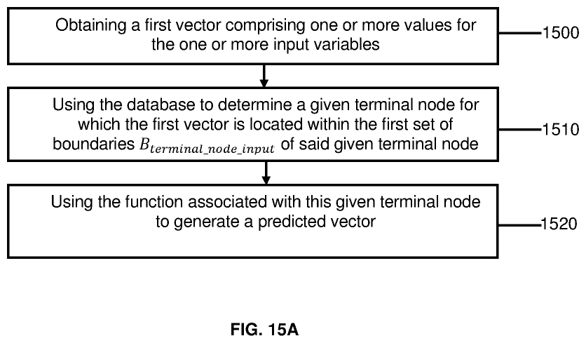

Attention is now drawn to FIG. 14.

The database can be used to determine whether there is a bias in the training of the machine learning model and/or whether the machine learning model should be retrained with a different or augmented training data set. In particular, it can be determined that a given input variable overly impacts the prediction provided by the machine learning model.

When a user trains a machine learning model, he generally has some knowledge of the phenomenon which is modelled by the machine learning model (alternatively, domain experts can have knowledge of the phenomenon which is modelled by the machine learning model). For example, assume that the machine learning model predicts a probability for a patient to have a disease based on different health indicators of a patient. If it is known (from scientific data) that some health indicators have a low impact on the probability to contract this disease, and the magnitude of the coefficients and/or the data D_{stat_sign} of the terminal nodes of the database indicates that these health indicators have a large impact on the probability to contract this disease, this indicates a bias (or failure) in the training of the machine learning model. Therefore, this can be used to output an indication that the machine learning model should be retrained.

Attention is now drawn to FIG. 14, which depicts a method of detecting whether the trained machine learning model is biased.

For example, assume that a trained machine learning model is trained to determine whether a given person is adequate for a given position in a firm, based on different input variables such as years of experience, university degree, etc.

The method can include collecting (operation 1400), for a first set of input variables (for example informative of a first group of people), corresponding coefficients (hereinafter first coefficients) of the terminal nodes in which the input variables of the first set are located. Note that the method of FIG. 13 can be used to determine the relevant terminal nodes. For each input variable, a distribution can be obtained for the first coefficients.

The method can include collecting (operation 1410), for a second set of input variables (for example informative of a second group of people), different from the first set of input variables, corresponding coefficients (hereinafter second coefficients) of the terminal nodes in which the input variables of the second set are located. Note that the method of FIG. 13 can be used to determine the relevant terminal nodes. For each input variable, a distribution can be obtained for the second coefficients.

The method further includes using (operation 1420) the first coefficients and the second coefficients to determine whether there is a bias in the trained machine learning model. In particular, if for a given input variable, it is determined that a coefficient (see e.g. coefficients α_{1,1} to α_{P,M}) tends to have a larger magnitude for the first set of input values with respect to the second set of input values, this can indicate a bias.

Similarly, if for the first set of input variables, the value of the intercept (see e.g. coefficients β₁ to β_{P}) tends to be larger than for the second set of input variables, this can indicate a bias.

Assume an example in which it is attempted to detect whether there is a bias in the trained machine learning model between men (first group of people) and women (second group of people). It can be detected that for a given input variable (e.g. number of years of study), the coefficient has a larger magnitude for men than for women. This indicates for two candidates who have the same years of study, the model tends to favour men.

Assume that the coefficients have the same magnitude for men and women, but it has been detected that the intercept is larger for men than for women. This indicates that for two candidates who have exactly the same profile, the model tends to favour men.

Note that the method of FIG. 14 enables not only to understand whether there is a bias, but also for which ranges of the input variables a bias is present. This can be deduced by comparing the coefficients obtained for each input variable, between two different sets of input variables, and by outputting the boundaries of the terminal nodes in which a bias has been detected.

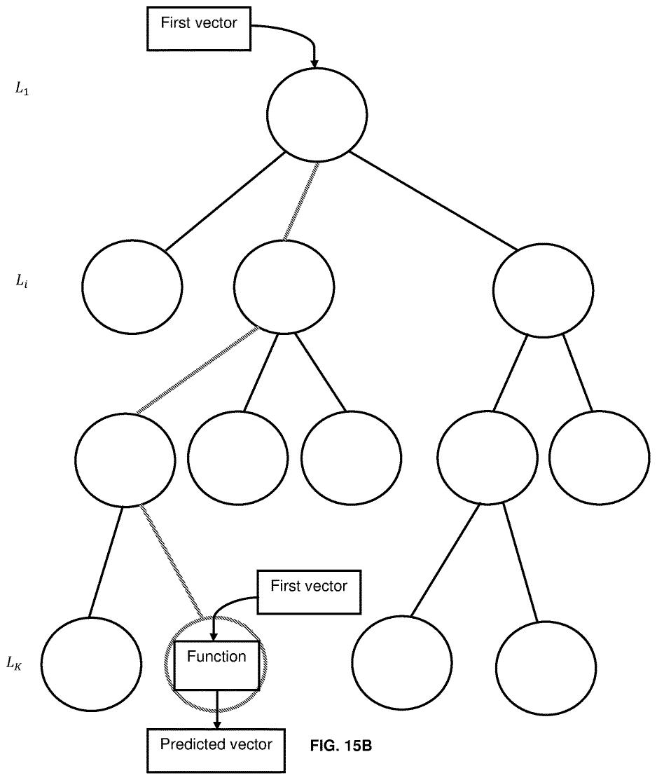

Attention is now drawn to FIG. 15A.

Assume that a database has been built (using one or more of the methods described above), which is informative of a given trained machine learning model.

The method of FIG. 15A includes obtaining (operation 1500) a first vector comprising one or more values for the one or more input variables.

Instead of feeding the first vector to the machine learning model itself to obtain a prediction by the trained machine learning model, the method includes using the database to determine the values for the output variables. Generally, this provides a quicker response (the time response is reduced), with a smaller computational effort. The response can be, in some cases, even more accurate than the prediction provided by the machine learning model itself.

The method includes determining (operation 1510) a terminal node of the database for which the first vector is located within the first set of boundaries B_{terminal_node_input} of said given terminal node. This can be performed by comparing the values of the first vector with the first set of boundaries B_{node_input} of the various nodes of the database, until a given terminal node is reached. The method of FIG. 12A can be used.

Once a given terminal node has been identified, the method can include using (operation 1520) the function associated with this given terminal node to generate a predicted vector (see illustration in FIG. 15B). Since the function models the “local” behaviour of the machine learning model, this enables to obtain a prediction which is an accurate estimate of the prediction which would have been output by the machine learning model based on the first vector, while being more computationally efficient.

For example, assume that the first vector is equal to

$$[ \begin{matrix}{X}_{1} \\ ⋮ \\ {X}_{M}\end{matrix} ] .$$

Then the predicted vector

$$[ \begin{matrix}{Y}_{1} \\ ⋮ \\ {Y}_{P}\end{matrix} ]$$

can be generated using the following equation.

$$[ \begin{matrix}{Y}_{1} \\ ⋮ \\ {Y}_{P}\end{matrix} ] = [ \begin{matrix}{α}_{1 , 1} & … & {α}_{1 , M} \\ ⋮ & ⋱ & ⋮ \\ {α}_{1 , P} & … & {α}_{P , M}\end{matrix} ] [ \begin{matrix}{X}_{1} \\ ⋮ \\ {X}_{M}\end{matrix} ] + [ \begin{matrix}{β}_{1} \\ ⋮ \\ {β}_{P}\end{matrix} ]$$

The coefficients

$$[ \begin{matrix}{α}_{1 , 1} & … & {α}_{1 , M} \\ ⋮ & ⋱ & ⋮ \\ {α}_{1 , P} & … & {α}_{P , M}\end{matrix} ]$$

and intercepts

$$[ \begin{matrix}{β}_{1} \\ ⋮ \\ {β}_{P}\end{matrix} ]$$

have been extracted from the given terminal node.

In a non-limitative example, assume that the machine learning model is trained to predict, based on input variables of a device (average temperature, average pressure, age of the device, etc.), the probability that the device will encounter a failure (output variable). The first vector can include, for a given device, values for the temperature, the pressure, and the age of the given device. Instead of feeding the first vector to the trained machine learning model, it is fed to the database in order to output a probability of failure.

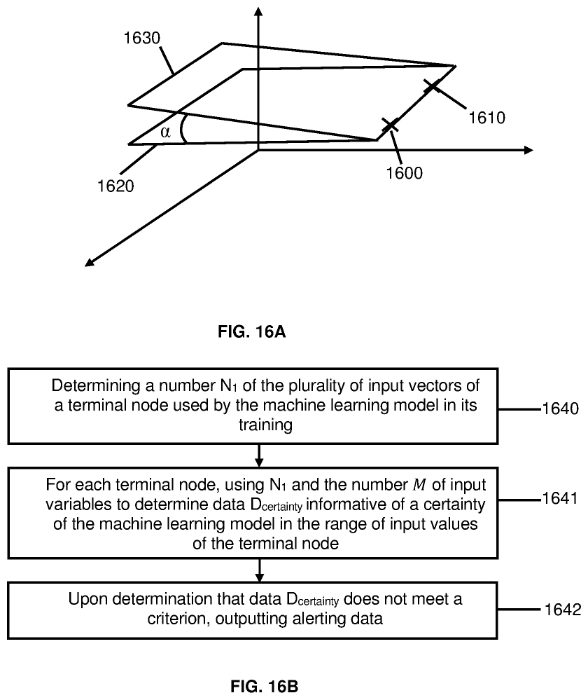

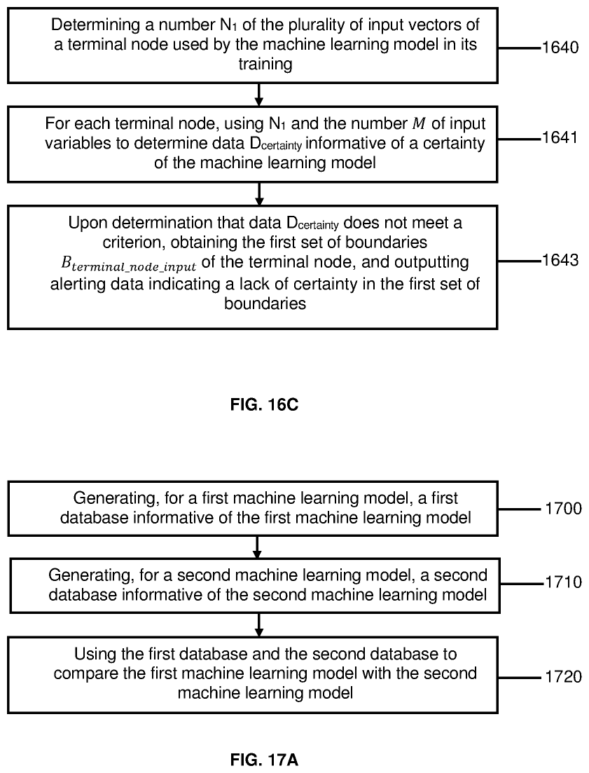

Attention is now drawn to FIGS. 16A and 16B.

When a machine learning model is trained by a set of labelled data points (ground truth values), it attempts to generate a “surface” that matches the label values to the greatest extent possible. The input vectors constitute the coordinates and the surface described by the machine learning model describes the approximated (predicted) value for each set of coordinates.

For example, assume that the machine learning model is trained to predict weather conditions based on input variables such as ambient temperature, ambient pressure, etc. In the training phase, the machine learning model is fed with input vectors (which include e.g., measurements of ambient temperature, ambient pressure) and with a label (real weather conditions for these measurements), and it attempts to generate a prediction which matches the label to the greatest extent possible.

It can occur that the machine learning model does not receive sufficient ground truth data, and, in this case, the machine learning model will be forced to make, during its training, “assumptions” which do not strongly rely on ground truth data. This is also known as Inference. It is advantageous to detect the level of inference in each decision, since a high level of inference is indicative of possible high levels of error in the prediction.

For example (see FIG. 16A), assume that the machine learning model predicts a single output variable based on two input variables. The machine learning model needs to generate a three-dimensional surface, and this requires at least three ground truth points. If the machine learning model receives, for a given area, only two ground truth points (see e.g., points 1600 and 1610 in FIG. 16A), there is an infinite number of possible solutions for a surface to pass through the two points and the machine learning model has to perform its own inference of the inclination a, which is not based on a sufficient number of ground truth points.

The machine learning model may therefore generate a function which corresponds to surface 1620, or with surface 1630, without relying on sufficient ground truth points for generating these surfaces.

Note that there is a correlation between high levels of errors in the observed model and localities where the model took high levels of inference to determine the exact inclination.

The method of FIG. 16B can be used to provide indication of whether the model has had sufficient ground truth data to determine the prediction surface, and the local level of inference the model had to use.

The method includes determining (operation 1640) a total number N₁ of input vectors which have been used to train the machine learning model, and which are associated with the terminal node.

Note that the terminal node can be associated with more than Nᵢ input vectors, since artificial input vectors (which have not been used during the training) may have been generated afterwards in order to generate the database, as explained with reference to FIG. 10A. The number of input vectors can be determined equivalently by determining the number of labels stored in the terminal node.

Assume that there are M input variables X₁ to X_{M} (with M≥1).

Operation 1641 includes using N₁ and M to determine data D_{certainty} informative of the certainty of the machine learning model be associated with the terminal node.

In some embodiments, D_{certainty} corresponds to the ratio between N₁ and M. The inverse of certainty (ratio between M and N₁) is called sparsity.

If the ratio is below a threshold (for example 1), this can indicate that the machine learning model has to perform some inference (and therefore the certainty of the machine learning model may be insufficient).

Note that the method of FIG. 16B can be performed for each of the terminal nodes of the database, or for at least some of them.

As a consequence, for each terminal node, it is possible to obtain data D_{certainty}. Since each terminal node is informative of a particular portion of the space of the input variables (defined by the boundaries of the input vectors—see FIG. 11), it is possible to determine the certainty of the machine learning model for each portion of the space of the input variables.

If it is determined that the ratio is below the threshold, the method can include generating alerting data (operation 1642).

According to some embodiments, the alerting data can indicate to the user (and/or to a computerized system) that the machine learning model has low certainty at the particular locality (this can be determined using the boundaries associated with the terminal node), and that more ground truth measurements may be required.

This is illustrated in FIG. 16C, which includes operations 1640 and 1641 of FIG. 16B, and further includes (operation 1643), upon detecting that data D_{certainty} does not meet a criterion, obtaining the first set of boundaries B_{terminal_node_input} of the terminal node.

As mentioned above, B_{terminal_node_input} defines the boundaries of a space in which all values of the plurality of input vectors of said terminal node are located.

It is therefore possible to output to the user the areas in which the prediction of the machine learning model tends to be certain/accurate (D_{certainty} is high) and the areas in which the prediction of the machine learning model tends to be uncertain/inaccurate (D_{certainty} is low). The areas can be identified by extracting the first set of boundaries B_{terminal_node_input} of the terminal node.

In some embodiments, if D_{certainty} indicates a lack of certainty, the method can include generating alerting data which indicates a lack of certainty of the machine learning model within the first set of boundaries B_{terminal_node_input}.

In some embodiments, the alerting data indicates that the machine learning model is to be retrained. In particular, the method can indicate to the user (and/or to a computerized system) in which areas the machine learning model is likely to be inaccurate. The method can indicate that the machine learning model should be retrained (in priority) with new input vectors located within the first set of boundaries B_{terminal_node_input}. The method points out to the user (and/or the system) in which areas he should focus when selecting new input vectors for the retraining of the machine learning model.

This enables to perform a retraining of the machine learning model which focuses on its weaknesses. The is particularly beneficial when data acquisition is expensive and/or cumbersome. In addition, the retraining is therefore more efficient and this reduces computation time.

A non-limitative example is provided hereinafter.

Assume that a training set describes the relationship between a set of input values and an illness (e.g., diabetes). Assume that the training set is not equally distributed, and in some areas there is a high density of data points, but in others area, there is a low density of data points (i.e. sparse areas).

Assume that the overall accuracy measured for this model is 70%, and it is desired to reach 90%. Given that each data point of the training set is a real measurement of a patient and needs to be acquired from a hospital, each data point is expensive. It is therefore crucial to acquire only data points that contribute to the improvement of the accuracy of the model. The methods as described above provide the areas of the input values in which data points should be acquired in priority.

According to some embodiments, the alerting data can inform the user (and/or a computerized system) that the machine learning model is not sufficiently accurate in its prediction in particular ranges of values of the input variables and/or that the model has more errors in particular areas of the data set.

According to some embodiments, the alerting data can inform the user (and/or a computerized system) that the machine learning model has to be retrained using different and/or augmented training data.

Note that the use of the database enables to provides pinpointed feedback to the user (and/or a computerized system) on the weaknesses/inaccuracy of the machine learning model.

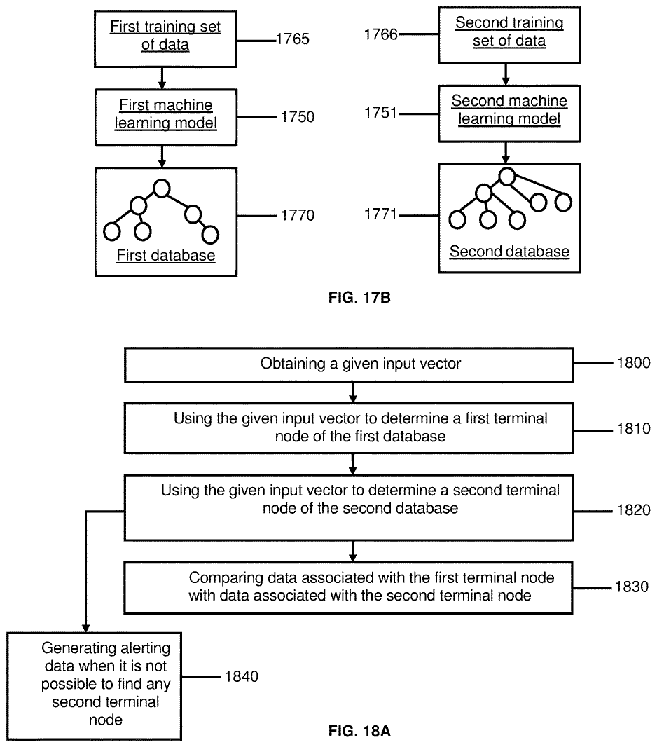

Attention is now drawn to FIGS. 17A and 17B.

In some embodiments, the user has an existing machine learning model (hereinafter old machine learning model) and wishes to develop a new version of this machine learning model (hereinafter new machine learning model).

In some embodiments, the new machine learning model differs from the old machine learning model in that a different training set is used to train the new machine learning model. The training set used for the new machine learning model can e.g., include additional data which were not present in the training set used for the old machine learning model.

Alternatively, the new machine learning model and the existing machine learning model may have been trained with the same training set, but differ in the algorithm implementation (e.g. XGBoost vs. ANN).

The development of a new machine learning model raises several questions for the user, such as whether the new machine learning model does not degrade the performance of the old machine learning model, whether the new machine learning model covers at least the space covered by the old machine learning model, etc.

For example, assume that the old machine learning model has been trained to detect the probability of old people to develop a certain disease. Assume that the new machine learning model is now trained with additional data informative of young people, in order to also detect the probability of young people to develop a certain disease. Since the coverage of the new machine learning model is different, this raises the question whether the new machine learning model performs at least as well as the old machine learning model, regarding other age groups.

In some cases, the user has two different machine learning models (which may involve a different architecture) and would like to compare these two machine learning models.

Assume that a first machine learning model 1750 has been trained using a first training set of data 1765. The first training set of data 1765 includes first input vectors (and corresponding labels). The first machine learning model 1750 is used to generate (after its training) first predicted vectors corresponding to the first input vectors.

Assume that a first database 1770 informative of the first machine learning model 1750 has been generated, using the first training set of data 1765 and the first predicted vectors. As mentioned above with reference to FIG. 10A, additional first input vectors, which have not been used to train the first machine learning model 1750, together with corresponding predicted vectors, can be obtained to generate the first database 1770.

Generation of the first database 1770 can rely on the various embodiments described above.

Assume that a second machine learning model 1751 has been trained using a second training set of data 1766. The second training set of data 1766 includes second input vectors (and corresponding labels). The second machine learning model 1751 is used to generate (after its training) second predicted vectors corresponding to the second input vectors.

Assume that a second database 1771 informative of the second machine learning model 1751 has been generated, using the second training set of data 1766 and the second predicted vectors. As mentioned above with reference to FIG. 10A, additional second input vectors, which have not been used to train the second machine learning model 1751, together with corresponding predicted vectors, can be obtained to generate the second database 1771.

Generation of the second database 1771 can rely on the various embodiments described above.

According to some embodiments, at least some of the second input vectors used to train the second machine learning model 1751 are different from the first input vectors used to train the first machine learning model 1750. This is however not mandatory.

According to some embodiments, the second machine learning model corresponds to the first machine learning model after a retraining using second input vectors different from the first input vectors.

According to some embodiments, the second machine learning model has a different architecture than the first machine learning model (different types of ML, network). In other embodiments, the first machine learning model and the second machine learning model have the same architecture.

The method can include using (operation 1720) the first database 1770 and the second database 1771 to compare the first machine learning model 1750 with the second machine learning model 1751. This comparison can be used to output data informative of a difference in performance, accuracy, coverage, etc. between the first machine learning model 1750 and the second machine learning model 1751.

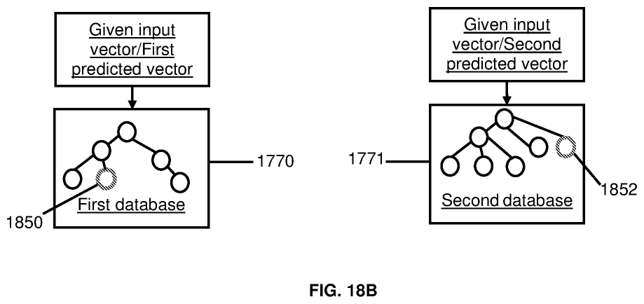

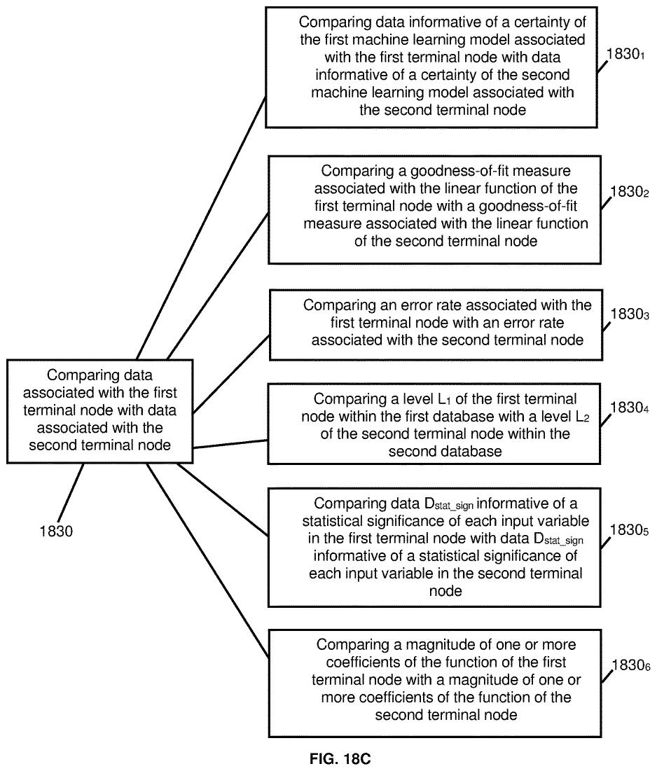

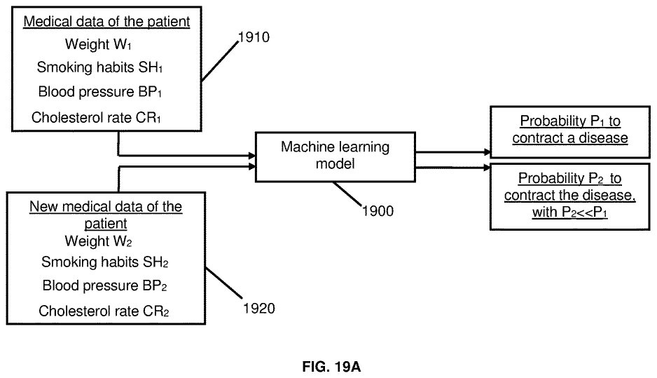

FIG. 18A depicts a method which can be used to compare the first machine learning model 1750 with the second machine learning model 1751.

The method includes obtaining (operation 1800) a given input vector. The given input vector can be selected by a user, in order to compare the first machine learning model to the second machine learning model for input values of interest.

In some embodiments, operation 1800 can include determining, for the given input vector, a first predicted vector generated by the first machine learning model.

In some embodiments, operation 1800 can further include determining, for the given input vector, a second predicted vector generated by the second machine learning model.

The method includes using (operation 1810) the given input vector to determine a first terminal node 1850 of the first database 1770. In particular, operation 1810 can rely on the method of FIG. 12A, in which a first terminal node is determined for which the given input vector is located within the first set of boundaries B_{terminal_node_input} of the first terminal node.

Similarly, the method includes using (operation 1820) the given input vector to determine a second terminal node 1852 of the second database 1771. In particular, operation 1820 can rely on the method of FIG. 12A, in which a second terminal node 1852 is determined for which the given input vector is located within the second set of boundaries B_{terminal_node_input} of the second terminal node 1852.

The method of FIG. 18A further includes comparing (operation 1830) data associated with the first terminal node with data associated with the second terminal node. This comparison enables to understand whether the second machine learning model performs better (or worse) than the first machine learning model. This is beneficial for the user (or a computerized system), who assesses whether it is worth using the second machine learning model or not, and whether the second machine learning model should be retrained. This is also beneficial to understand whether the second machine learning model is an improvement of the first machine learning model. If no improvement is detected, the training set of the second machine learning model and/or the implementation of the second machine learning model can be changed.

In some cases, it can occur that it is not possible to find any second terminal node in the second database which has a second set of boundaries B_{terminal_node_input} including the given input vector. This indicates to the user that the second machine learning model has a more limited/smaller coverage.

This can be used to indicate to the user that the training set of the second machine learning model should be augmented, to improve model performance. In particular, it can be indicated that the training set should include input vectors located within the first set of boundaries of the first terminal node.

In some cases, the method can include outputting alerting data (operation 1840) which alerts e.g., the user (and/or a computerized system) that the coverage of the second machine learning model is not as large as the coverage of the first machine learning model.

According to some embodiments, operation 1830 can include comparing (operation 1830₁ in FIG. 18D) data informative of a certainty of the first machine learning model associated with the first terminal node with data informative of a certainty of the second machine learning model associated with the second terminal node. Embodiments for computing data, informative of a certainty of a given terminal node, have been described with reference to FIGS. 16A to 16C. This enables to understand whether the second machine learning model provides a prediction with a higher (or lower) certainty than the first machine learning model. The user can therefore understand whether the second machine learning model performs better than the first machine learning model, and this can impact his decision to deploy/use the second machine learning model instead of the first machine learning model. In particular, a detailed report on the difference in global and/or local performance between the two models can be provided.

In particular, the user can understand for which values of the input variables the second machine learning model has a higher certainty (or lower certainty) in its prediction than the first machine learning model. This can be used to retrain the second machine learning model with input values which are specifically targeted in the areas in which the second machine learning model has a lower certainty than the first machine learning model.

Assume that the method of FIG. 18C indicates that for the given input vector, a second terminal node has been identified which is associated with a lower certainty than the first terminal node. Since the second terminal node is associated with boundaries (B_{terminal_node_input}), it is possible to retrain the second machine learning model with input values located in the boundaries B_{terminal_node_input}.

Alternatively, it is possible to create an ensemble which includes the first machine learning model and the second machine learning model: for input values within B_{terminal_node_input}, the first machine learning model is used, and for other input values, the second machine learning model is used.

Alternatively, it is possible to disregard the second machine learning model and to use only the first machine learning model.

According to some embodiments, operation 1830 can include comparing (operation 18302 in FIG. 18C) a goodness-of-fit measure associated with the function of the first terminal node with a goodness-of-fit measure associated with the function of the second terminal node. Examples of goodness-of-fit measure include e.g., the R-squared (R²) value. This enables to understand which model performs better. Based on this comparison, a decision can be taken, as explained above (including e.g. retraining, creating an ensemble, disregarding one of the machine learning model, etc.). The comparison can be performed per input variable.

According to some embodiments, operation 1830 can include comparing (operation 18303 in FIG. 18C) an error rate associated with the first terminal node with an error rate associated with the second terminal node. The error of each terminal node can be computed by comparing the prediction values generated by the machine learning model with the ground truth values, or by comparing the predictions that are based on the function of the terminating node with the ground truth values.

Based on the comparison of the error rate between the two terminal nodes, a decision can be taken as described above.

According to some embodiments, operation 1830 can include comparing (operation 1830₄ in FIG. 18C) a level L₁ of the first terminal node within the first database with a level L₂ of the second terminal node within the second database. The level of a terminal node (or of a node) can be defined as the number of nodes between the terminal node and the root node.

If L₂ is higher than L₁, this indicates that it is necessary to search deeper in the hierarchical architecture of the second database to find the same input vector, and this indicates that second machine learning model has a more volatile behaviour (less linear behaviour) than the first machine learning model. This may be an indicator that there is a need to retrain the second machine learning model.

According to some embodiments, operation 1830 can include comparing (operation 1830₅ in FIG. 18C), for each input variable, of data D_{stat_sign} informative of a statistical significance of the input variable in the function of the first terminal node with data D_{stat_sign} informative of a statistical significance of the input variable in the function of the second terminal node. Similarly, operation 18306 can include, for each input variable, comparing the magnitude of the coefficient associated with this input variable for the first terminal node with the magnitude of the coefficient associated with this input variable for the second terminal node.

In case the second machine learning model corresponds to the first machine learning model trained with new and/or augmented data, or to a different implementation of the first machine learning model, this enables to understand the change that the retraining with the new/augmented data or the change in implementation had on the “surface” created by the observed model.

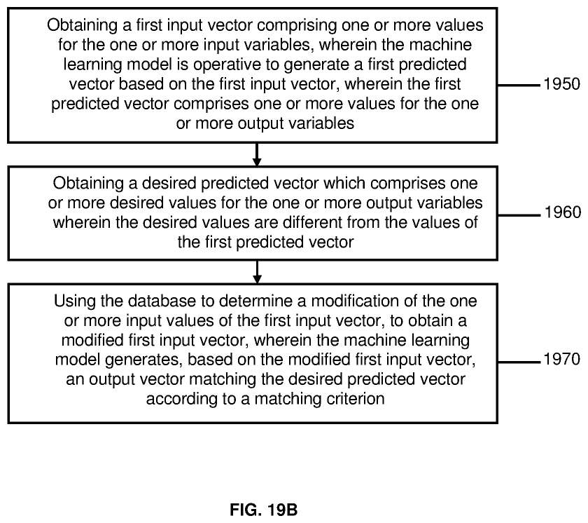

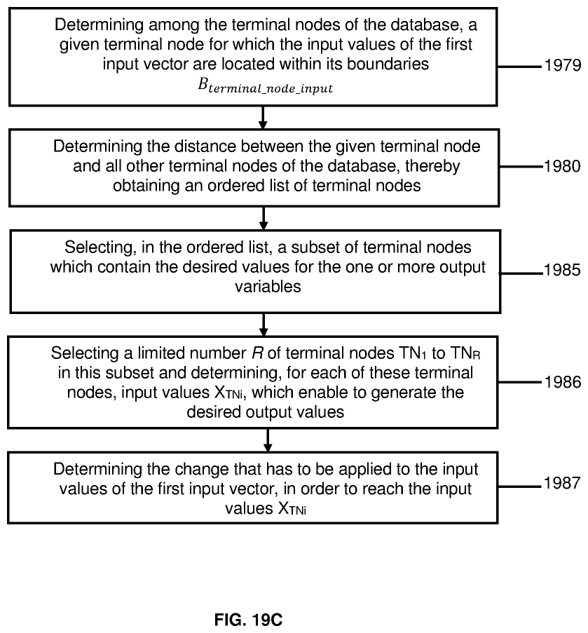

Attention is now drawn to FIGS. 19A and 19B.

FIG. 19A illustrates, with a simple example, a possible application of the method of FIG. 19B. Note that the example of FIG. 19A is not limitative.

Assume that the machine learning model 1900 is trained to predict, based on medical data informative of a patient (e.g., weight, smoking habits, blood pressure, cholesterol rate), the probability that the patient can suffer from a certain disease.

Assume that a given patient is associated with medical data 1910 and the machine learning model 1900 predicts that the given patient has a high probability P₁ to contract a certain disease. The given patient and/or the doctor is interested to know how to modify the medical data 1910 in order to get a much lower probability P₂ to contract the certain disease. The method of FIG. 19A indicates to the patient new medical data 1920 that will enable him to get the lower probability P₂. For example, assume that the new medical data indicates a lower weight. The patient therefore understands that he should follow a diet to reach this lower weight, thereby reducing the probability to contract the given disease.

Note that this example is not limitative and various other applications can be found, such as:
a machine learning model is trained to predict whether a client of a bank is an appropriate candidate to receive a loan, and the client would like to know how he could modify his profile to get a positive answer;
a machine learning model is trained to predict the lifetime of an electronic appliance based on operating parameters (temperature, etc.) of the electronic appliance, and the user would like to understand the optimal way to use the electronic appliance in order to maximize its lifetime;
a machine learning model is trained to determine the probability that a supplier of a production plant will be able to deliver goods within the required period of time, based on parameters of the plant, of the goods, and of the supplier, and the user would like to understand the optimal parameters that will ensure delivering of the goods in time;
other applications.

Reverting to FIG. 19B, the method includes obtaining (operation 1950) a data point which includes:
a first input vector comprising one or more values for the one or more input variables, and
a first predicted vector generated by the machine learning model using the first input vector, wherein the first input vector comprises one or more values for the one or more output variables.

In the example of FIG. 19A, the first input vector corresponds to the medical data 1910 and the first predicted vector corresponds to the probability P₁.

The method includes obtaining (operation 1960) a desired data point, which includes a desired predicted vector which comprises one or more desired values for the one or more output variables, wherein the desired values are different from the values of the first predicted vector. In the example of FIG. 19A, the desired predicted vector corresponds to the probability P₂.

The method further includes using (operation 1970) the database to determine a modification of the one or more values of the first input vector, to obtain a modified first input vector. In the example of FIG. 19A, the modified first input vector corresponds to the new medical data 1920.

In particular, when the machine learning model receives the modified first input vector as an input, it generates an output vector matching the desired predicted vector according to a matching criterion. The matching criterion can define the maximal acceptable error between the desired predicted vector and the desired second vector (e.g., below 5 or 10 percent, these values being not limitative).

According to some embodiments, operation 1970 can include determining the modified first input vector which requires the smallest possible modifications of the first input vector, while ensuring that the machine learning model outputs an output vector matching the desired predicted vector.

FIG. 19C illustrates a possible implementation of operation 1970 of the method of FIG. 19B.

The method includes determining (operation 1979) among the terminal nodes of the database, a given terminal node for which the input values of the first input vector are located within its boundaries B_{terminal_node_input}.

The method includes determining (operation 1980) the distance between the given terminal node and all other terminal nodes of the database. This can include determining the center of the given terminal node: since all data points of the given terminal node are known, it is possible to determine the center of the given terminal node (for instance by determining the center of gravity of the data points). Similarly, the center of each of the other terminal nodes can be determined. The distance between the given terminal node and all other terminal nodes can be calculated by determining the distance between the center of the given terminal node and the center of each of the other terminal nodes. The distance can be determined using a formula based e.g. on Euclidean distance.

As a consequence, a list of terminal nodes is obtained, which is ordered based on the distance to the given terminal node.

The method further includes selecting (operation 1985), in the ordered list, a subset of terminal nodes which contain the desired values for the one or more output variables. In other words, for each of these terminal nodes, the space defined by the output of the function of these terminal nodes contain the desired values for the one or more output variables.

In order to determine whether a terminal node includes the desired values, it is possible to use the function of this terminal node, and to determine all possible values that the function of this terminal node can output (by feeding to the function the whole space of the input values of this terminal node). Alternatively, it is possible to check, within the data points associated with the terminal node, whether these data points include the desired values for the one or more output variables.

Following operation 1985, a subset of terminal nodes (ordered by their distance to the given terminal node), which each include the desired values for the one or more output variables, is obtained.

The method further includes selecting (operation 1986) a limited number R of terminal nodes TN₁ to TN_{R} in this subset (note that this number can be selected by a user).

For each terminal node TN₁ to TN_{R}, it is known that the desired values for the output variables are located in the space defined by each of these terminal nodes. Therefore, for each terminal node TN₁ to TN_{R}, the corresponding input values X_{TNi}, which enable to generate these desired output values, can be obtained, using the function associated with each of the terminal nodes.

For each terminal node (within this limited number of terminal nodes), it is determined (operation 1987) the change that has to be applied to the input values of the first vector, in order to reach the input values X_{TNi} (this can be obtained by performing a subtraction). Note that it is possible that for a given terminal node T_{Ni}, different sets of input values X_{TNi} can exist, which all enable to obtain the desired output values. It is therefore possible to select, for each terminal node T_{Ni}, the input values X_{TNi} which require the smallest modifications of the input values of the first vector.

The required modification can be output to the user, and/or to a computerized system. It is therefore known how to modify the first vector in order to obtain, by the machine learning model, the desired prediction.

Embodiments of the presently disclosed subject matter are not described with reference to any particular programming language. It will be appreciated that a variety of programming languages may be used to implement the teachings of the presently disclosed subject matter as described herein.

The invention contemplates a computer program being readable by a computer for executing one or more methods of the invention. The invention further contemplates a machine-readable memory tangibly embodying a program of instructions executable by the machine for executing one or more methods of the invention.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. The various features described in the various embodiments may be combined according to all possible technical combinations.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

1-50. (canceled)

51. A system comprising at least one processor and memory circuitry (PMC) configured to:
obtain, for a machine learning model, a set of data points, informative of a set of input vectors and of a set of predicted vectors, wherein each input vector of the set of input vectors has been used to train the machine learning model, wherein each given data point of the set of data points is associated with:
a given input vector of the set of input vectors,
a given predicted vector of the set of predicted vectors, wherein the given predicted vector has been generated by the machine learning model using the given input vector,
use the set of data points to generate a database informative of the machine learning model, wherein the database is informative of a plurality of nodes comprising terminal nodes, wherein each given terminal node is associated with:
a plurality of data points of the set of data points,
one or more coefficients defining a function, wherein the function fits a relationship between:
a plurality of input vectors of the plurality of data points of the given terminal node, and
a plurality of predicted vectors of the plurality of data points of the given terminal node, with a quality meeting an accuracy criterion,
wherein the database is usable to generate data informative of the machine learning model.

52. The system of claim 51, configured to use the database for at least one of:
(i) determining data informative of a quality of the training of the machine learning model;
(ii) determining a certainty of the machine learning model in its prediction;
(iii) determining a certainty of a prediction generated by the machine learning model depending on a range of values of input vectors fed to the machine learning model;
(iv) providing a recommendation of whether the machine learning model has to be retrained;
(v) providing a recommendation on a range of values of input vectors for which the machine learning model has to be retrained;
(vi) determining one or more input variables of the input vectors which most impact a prediction generated by the machine learning model;
(vii) determining a change in one or more values of a given input vector to obtain a prediction, by the machine learning model, which matches a desired predicted vector;
(viii) for a given input vector, estimating a prediction which would have been generated by the machine learning model using this given input vector; or
(ix) determining data informative of a bias in a prediction of the machine learning model.

53. The system of claim 51, wherein at least one of (i) or (ii) is met:
(i) each terminal node is associated with a first set of boundaries B_{terminal_node_input} defining boundaries of a space in which all of the plurality of input vectors of the data points of the terminal node are located;
(ii) the plurality of nodes includes non-terminal nodes and terminal nodes, wherein at least one non-terminal node is linked to one or more child nodes, each child node being either a non-terminal node or a terminal node, said at least one non-terminal node being associated with a first set of boundaries B_{node_input} defining boundaries of a space in which all of the plurality of input vectors of all data points of said one or more child nodes are located

54. The system of claim 51, wherein at least one of (i) or (ii) is met:
(i) at least one terminal node is further associated with one or more data points, each of these data points including an input vector which have not been used to train the machine learning model and a predicted vector generated by the machine learning model using the input vector;
(ii) each terminal node of the plurality of terminal nodes of the database is associated with a first set of boundaries B_(terminal_node_input) defining boundaries of a space in which all values of the plurality of input vectors of all data points of said terminal node are located, wherein, the system is configured to determine a lack of certainty of the machine learning model within the first set of boundaries B_(terminal_node_input).

55. The system of claim 51, wherein at least one of (i), (ii) or (iii) is met:
(i) each input vector comprises one or more values for one or more input variables, wherein, for a function of at least one terminal node, each given input variable is associated with data Dstat_sign informative of a statistical significance of the input variable;
(ii) each input vector comprises one or more values for one or more input variables and each predicted vector comprises one or more values for one or more output variables, wherein, for a given terminal node, the function defines a relationship between the input variables and the output variables, determined using the plurality of input vectors of the given terminal node and the plurality of predicted vectors of the given terminal node;
(iii) each input vector comprises one or more values for one or more input variables, wherein, for a function of at least one terminal node, each input variable is associated with a coefficient in the function.

56. The system of claim 51, wherein at least one of (i) or (ii) is met:
(i) the system is configured to, for one or more of input variables of the input vectors, use a magnitude of a coefficient associated with the input variable to determine data informative of an impact of the given input variable on a prediction of the machine learning model;
(ii) the system is configured to use coefficients associated with input variables of the input vectors to determine whether the machine learning model relies more on a limited subset of one or more input variables than one or more input variables which are not part of the subset to generate its prediction.

57. The system of claim 51, wherein:
each input vector comprises one or more values for one or more input variables,
each terminal node of the plurality of terminal nodes of the database is associated with a first set of boundaries B_{terminal_node_input} defining boundaries of a space in which all values of the plurality of input vectors of the data points of said terminal node are located, wherein at least one of (i), (ii) or (iii) is met:
(i) the system is configured to obtain a data point comprising a first vector comprising one or more values for the one or more input variables, and use the database to determine a given terminal node for which the first vector is located within the space defined by the first set of boundaries B_{terminal_node_input} of said given terminal node;
(ii) each predicted vector comprises one or more values for one or more output variables, wherein the system is configured to obtain a first vector comprising one or more values for the one or more input variables, use the database to determine a given terminal node for which the first vector is located within the space defined by the first set of boundaries B_{termninal_node_input} of said given terminal node, use the function associated with said given terminal node and the first vector to determine a second vector comprising one or more values for the one or more output variables;
(iii) for one or more of the input variables, the system is configured to use a magnitude of a coefficient associated with the input variable to determine data informative of an impact of the given input variable on a prediction of the machine learning model in a range of input values located within the first set of boundaries.

58. The system of claim 51, wherein each input vector is informative of M input variables, wherein the system is configured to, for at least one terminal node, obtain a number N1 of data points associated with the terminal node which include an input vector which has been used to train the machine learning model, and use N1 and M to determine data D_{certainty} informative of the certainty of the machine learning model associated with the terminal node.

59. The system of claim 51, wherein at least one of (i) or (ii) is met:
(i) any data point including an input vector of the set of input vectors and a corresponding predicted vector of the set of predicted vectors is associated with a single terminal node of the database;
(ii) the plurality of nodes is arranged in hierarchical levels Lᵢ, with i from 1 to N, wherein each node of level Lⱼ is linked to a parent node of level Lⱼ₋₁, with j from 2 to N, wherein each node is associated with a first set of boundaries B_{node_input} defining boundaries of a space including input vectors of all data points associated with this node, wherein, for each given node linked to a parent node, a space defined by the first set of boundaries of the given node is included within the space defined by the first set of boundaries of the parent node

60. The system of claim 51, wherein generating the database comprises:
(1) obtaining a given node associated with a plurality of data points of the set of data points,
(2) determining coefficients defining a function which fits a relationship between the plurality of input vectors and the plurality of predicted vectors of the data points of the given node,
(3) determining whether the function fits the relationship between the plurality of input vectors and the plurality of predicted vectors of the data points of the given node with a quality meeting an accuracy criterion,
(4) for a function for which said quality does not meet the accuracy criterion:
generating N child nodes linked to the given node, with N≥1, each given child node being associated with a given fraction of the data points of the parent node, and
repeating (1) to (3) for each given child node, wherein said repeating of (1) to (3) for each given child node comprises using the given child node as the given node in (1) to (3).

61. The system of claim 60, wherein, at least one of (i), (ii), (iii) or (iv) is met:
(i) upon determination at (3) that the function fits the relationship between the plurality of input vectors and the plurality of predicted vectors of the data points of the given node with a quality meeting the accuracy criterion, the system is configured to store the given node as a terminal node in the database;
(ii) for a given child node being associated with a given number M1 of data points which is below a threshold, the system is configured to obtain one or more additional input vectors which have not been used to train the machine learning model, use the one or more additional input vectors to generate, by the machine learning model, additional predicted vectors, and associate data points including the additional input vectors and the additional predicted vectors with the given child node;
(iii) the given number M1 of data points only include input vectors which have been used to train the machine learning model;
(iv) the given child node is associated with a first set of boundaries B_{node_input} defining boundaries of a space including the M1 input vectors of the data points associated with the given child node, wherein the one or more additional input vectors are selected within the first set of boundaries B_{node_input}.

62. The system of claim 51, configured to:
obtain, for a first machine learning model, a first set of data points, informative of a first set of input vectors and of a first set of predicted vectors, wherein each input vector of the first set of input vectors has been used to train the machine learning model, wherein each given data point of the first set of data points is associated with:
a given input vector of the first set of input vectors, and
a given predicted vector of the first set of predicted vectors,
wherein the given predicted vector has been generated by the machine learning model using the given input vector,
use the first set of data points to generate a first database informative of the first machine learning model, wherein the first database is informative of a plurality of nodes comprising terminal nodes, wherein, for at least part of the terminal nodes, each given terminal node is associated with:
a plurality of data points of the first set of data points,
one or more coefficients defining a function, wherein the function fits a relationship between:
a plurality of input vectors of the plurality of data points of the given terminal node, and
a plurality of predicted vectors of the plurality of data points of the given terminal node, with a quality meeting an accuracy criterion,
obtain, for a second machine learning model, a second set of data points, informative of a second set of input vectors and of a second set of predicted vectors, wherein each input vector of the second set of input vectors has been used to train the machine learning model, wherein each given data point of the second set of data points is associated with:
a given input vector of the second set of input vectors, and
a given predicted vector of the second set of predicted vectors
wherein the given predicted vector has been generated by the machine learning model using the given input vector,
use the second set of data points to generate a second database informative of the second machine learning model, wherein the second database is informative of a plurality of nodes comprising terminal nodes, wherein, for at least part of the terminal nodes, each given terminal node is associated with:
a plurality of data points of the second set of data points,
one or more coefficients defining a function, wherein the function fits a relationship between:
a plurality of input vectors of the plurality of data points of the given terminal node, and
a plurality of predicted vectors of the plurality of data points of the given terminal node, with a quality meeting an accuracy criterion, and
use the first database and the second database to compare data informative of the first machine learning model with data informative of the second machine learning model.

63. The system of claim 62, wherein at least one of (i), (ii), (iii), (iv), (v), (vi) or (vii) is met:
(i) at least some of the second input vectors used to train the second machine learning model are different from the first input vectors used to train the first machine learning model;
(ii) the second machine learning model corresponds to the first machine learning model after a retraining using second input vectors different from the first input vectors;
(iii) an architecture of the second machine learning model differs from an architecture of the first machine learning model.
(iv) the system is configured to determine, for a given input vector, a first terminal node of the first database for which a first set of boundaries of the first terminal node contains the given input vector, determine, for the given input vector, a second terminal node of the first database for which a first set of boundaries of the second terminal node contains the given input vector, and compare at least one of data associated with the first terminal node with data associated with the second terminal node, data informative of a certainty of the first machine learning model associated with the first terminal node with data informative of a certainty of the second machine learning model associated with the second terminal node, a goodness-of-fit measure associated with the function of the first terminal node with a goodness-of-fit measure associated with the function of the second terminal node, or a level of the first terminal node within the first database with a level of the second terminal node within the second database;
(v) the system is configured to compare, for at least one input variable, data D_{stat_sign} informative of a statistical significance of the input variable in the first terminal node with data D_{stat_sign} informative of a statistical significance of the input variable in the second terminal node;
(vi) the system is configured to compare, for at least one input variable, a magnitude of a coefficient associated with this input variable for the first terminal node with a magnitude of a coefficient associated with this input variable for the second terminal node; or
(vii) the system is configured to determine, for a given input vector, a first terminal node of the first database for which a first set of boundaries of the first terminal node contains the given input vector, wherein, when the second database does not include any terminal node which has a first set of boundaries defining a space including the given input vector, outputting alerting data.

64. The system of claim 51, wherein:
each input vector comprises one or more values for one or more input variables,
each predicted vector comprises one or more values for one or more output variables,
wherein the system is configured to:
obtain a first input vector comprising one or more values for the one or more input variables, wherein the machine learning model is operative to generate a first predicted vector by using the first input vector, wherein the first predicted vector comprises one or more values for the one or more output variables,
obtain a desired predicted vector which comprises one or more desired values for the one or more output variables, wherein the desired values are different from the values of the first predicted vector, and
use the database to determine a modification of the one or more input values of the first input vector, to obtain a modified first input vector, wherein the machine learning model generates, based on the modified first input vector, an output vector matching the desired predicted vector according to a matching criterion.

65. A non-transitory computer-readable memory by at least one computer, tangibly embodying a program of instructions executable by the at least one computer to perform:
obtaining, for a machine learning model, a set of data points, informative of a set of input vectors and of a set of predicted vectors, wherein each input vector of the set of input vectors has been used to train the machine learning model, wherein each given data point of the set of data points is associated with:
a given input vector of the set of input vectors,
a given predicted vector of the set of predicted vectors, wherein the given predicted vector has been generated by the machine learning model using the given input vector,
using the set of data points to generate a database informative of the machine learning model, wherein the database is informative of a plurality of nodes comprising terminal nodes, wherein each given terminal node is associated with:
a plurality of data points of the set of data points,
one or more coefficients defining a function, wherein the function fits a relationship between:
a plurality of input vectors of the plurality of data points of the given terminal node, and
a plurality of predicted vectors of the plurality of data points of the given terminal node, with a quality meeting an accuracy criterion,
wherein the database is usable to generate data informative of the machine learning model.

66. The non-transitory computer readable medium of claim 65, comprising instructions that, when executed by the at least one computer, cause the at least one computer to use the database for at least one of:
(i) determining data informative of a quality of the training of the machine learning model;
(ii) determining a certainty of the machine learning model in its prediction;
(iii) determining a certainty of a prediction generated by the machine learning model depending on a range of values of input vectors fed to the machine learning model;
(iv) providing a recommendation of whether the machine learning model has to be retrained;
(v) providing a recommendation on a range of values of input vectors for which the machine learning model has to be retrained;
(vi) determining one or more input variables of the input vectors which most impact a prediction generated by the machine learning model;
(vii) determining a change in one or more values of a given input vector to obtain a prediction, by the machine learning model, which matches a desired predicted vector;
(viii) for a given input vector, estimating a prediction which would have been generated by the machine learning model using this given input vector; or
(ix) determining data informative of a bias in a prediction of the machine learning model.

67. A database informative of a machine learning model, wherein the machine learning model is associated with:
a set of data points, informative of a set of input vectors and of a set of predicted vectors, wherein each input vector of the set of input vectors has been used to train the machine learning model, wherein each given data point of the set of data points is associated with:
a given input vector of the set of input vectors,
a given predicted vector of the set of predicted vectors, wherein the given predicted vector has been generated by the machine learning model using the given input vector,
wherein the database is informative of a plurality of nodes comprising terminal nodes, wherein each given terminal node is associated with:
a plurality of data points of the set of data points,
one or more coefficients defining a function, wherein the function fits a relationship between:
a plurality of input vectors of the plurality of data points of the given terminal node, and
a plurality of predicted vectors of the plurality of data points of the given terminal node, with a quality meeting an accuracy criterion,
wherein the database is usable to generate data informative of the machine learning model.

68. The database of claim 67, wherein at least one of (i), (ii), (iii), (iv) or (v) is met:
(i) one terminal node is further associated with one or more data points, each of these data points including an input vector which have not been used to train the machine learning model and a predicted vector generated by the machine learning model using the input vector;
(ii) each given terminal node is associated with a first set of boundaries B_{terminal_node_input} defining boundaries of a space in which all of the plurality of input vectors of all data points associated with the given terminal node are located;
(iii) for a function of at least one terminal node, each given input variable is associated with data D_{stat_sign} informative of a statistical significance of the input variable;
(iv) the plurality of nodes includes non-terminal nodes and terminal nodes, wherein at least one non-terminal node is linked to one or more child nodes, each child node being either a non-terminal node or a terminal node, said at least one non-terminal node being associated with a first set of boundaries B_{node_input} defining boundaries of a space in which all of the plurality of input vectors of all data points of said at least one or more child nodes are located;
(v) any data point including an input vector of the set of input vectors and a corresponding predicted vector of the set of predicted vectors is associated with a single terminal node of the database.

69. The database of claim 67, wherein at least one of (i) or (ii) is met:
(i) the plurality of nodes is arranged in hierarchical levels Lᵢ, with i from 1 to N, wherein each node of level Lⱼ is linked to a parent node of level Lⱼ₋₁, with j from 2 to N, wherein:
each node is associated with a first set of boundaries B_{node_input} defining boundaries of a space including input vectors of all data points associated with this node,
wherein, for each given node linked to a parent node, a space defined by the first set of boundaries of the given node is included within the space defined by the first set of boundaries of the parent node;
(ii) each input vector is informative of M input variables, wherein the database includes, for at least one terminal node, data D_{certainty} informative of the certainty of the machine learning model associated with the terminal node, wherein D_{certainty} is obtained using a number N₁ of data points associated with the terminal node which include an input vector which has been used to train the machine learning model, and M.

70. The database of claim 67, wherein the database is usable for at least one of:
(i) determining data informative of a quality of the training of the machine learning model; or
(ii) determining a certainty of the machine learning model in its prediction; or
(iii) determining a certainty of a prediction generated by the machine learning model depending on a range of values of input vectors fed to the machine learning model; or
(iv) providing a recommendation of whether the machine learning model has to be retrained; or
(v) providing a recommendation on a range of values of input vectors for which the machine learning model has to be retrained; or
(vi) determining one or more input variables of the input vectors which most impact a prediction generated by the machine learning model; or
(vii) determining a change in one or more values of a given input vector to obtain a prediction, by the machine learning model, which matches a desired predicted vector; or
(viii) for a given input vector, estimating a prediction which would have been generated by the machine learning model using this given input vector; or
(ix) determining data informative of a bias in a prediction of the machine learning model.
